(19) United States
(12) Patent Application Publication
(10) Pub. No.: US 2024/0118611 A1
(43) Pub. Date: Apr. 11, 2024

(54) TRANSFER FILM AND PHOTOSENSITIVE COMPOSITION

(71) Applicant: FUJIFILM Corporation, Tokyo (JP)

(72) Inventors: Kunihiko KODAMA, Fujinomiya-shi (JP); Keigo YAMAGUCHI, Fujinomiya-shi (JP)

(73) Assignee: FUJIFILM Corporation, Tokyo (JP)

(21) Appl. No.: 18/467,889

(22) Filed: Sep. 15, 2023

Related U.S. Application Data
(63) Continuation of application No. PCT/JP22/11219, filed on Mar. 14, 2022.

(30) Foreign Application Priority Data
Mar. 16, 2021 (JP) 2021-042323

(51) Int. Cl. G03F 7/038; C08F 212/08; C08F 212/14; C08F 220/18; C08F 220/28; G03F 7/033; G03F 7/039

(52) U.S. Cl. CPC G03F 7/038; C08F 212/08; C08F 212/22; C08F 220/1808; C08F 220/1811; C08F 220/283; G03F 7/033; G03F 7/039

(57) ABSTRACT

An object of the present invention is to provide a transfer film and a photosensitive composition, with which a film having excellent low moisture permeability and excellent scratch resistance can be formed. The transfer film of the present invention is a transfer film including a temporary support and a photosensitive layer, in which the photosensitive layer contains a polymer A and a compound β, the polymer A has a repeating unit (a) having a carboxy group linked to a main chain by a linking group having 1 or more carbon atoms, and the compound β has a structure b0 which reduces an amount of the carboxy group included in the polymer A by exposure.

### CROSS-REFERENCE TO RELATED APPLICATIONS

This application is a Continuation of PCT International Application No. PCT/JP2022/011219 filed on Mar. 14, 2022, which claims priority under 35 U.S.C. § 119(a) to Japanese Patent Application No. 2021-042323 filed on Mar. 16, 2021. The above applications are hereby expressly incorporated by reference, in their entirety, into the present application.

### BACKGROUND OF THE INVENTION

### 1. Field of the Invention

The present invention relates to a transfer film and a photosensitive composition.

### 2. Description of the Related Art

In a display device provided with a touch panel such as a capacitive input device (specifically, a display device such as an organic electroluminescence (EL) display device and a liquid crystal display device), a conductive pattern such as an electrode pattern corresponding to a sensor in a visual recognition portion and a wiring line for a peripheral wiring portion and a lead-out wiring portion is provided inside the touch panel.

On the conductive pattern, for example, for the purpose of preventing problems such as metal corrosion, increased electrical resistance between electrodes and drive circuits, and disconnection, a resin pattern is disposed as a protective film (permanent film). For example, a transfer film is used for forming the resin pattern.

For example, WO2013/084886A discloses a photosensitive element including a support film and a photosensitive layer which consists of a predetermined photosensitive resin composition and is provided on the support film.

### SUMMARY OF THE INVENTION

In a case of studying the transfer film (photosensitive element) in the related art such as WO2013/084886A, the present inventors have found that at least one of low moisture permeability or scratch resistance is deteriorated.

Specifically, it has been found that, by bonding the transfer film to an object to be transferred and exposing the transfer film, the obtained film has high moisture permeability and/or a low hardness.

Therefore, an object of the present invention is to provide a transfer film with which a film having excellent low moisture permeability and excellent scratch resistance can be formed. Another object of the present invention is to provide a photosensitive composition.

As a result of intensive studies on the above-described objects, the present inventors have found that the above-described objects can be accomplished by the following configurations.

[1]

A transfer film comprising:
a temporary support; and
a photosensitive layer,
in which the photosensitive layer contains a polymer A and a compound β,
the polymer A has a repeating unit (a) having a carboxy group linked to a main chain by a linking group having 1 or more carbon atoms, and
the compound β has a structure b0 which reduces an amount of the carboxy group included in the polymer A by exposure.

[2]

The transfer film according to [1],
in which the repeating unit (a) has one or more selected from the group consisting of a repeating unit represented by Formula (a1) described later and a repeating unit represented by Formula (a2) described later.

[3]

The transfer film according to [2],
in which X in Formula (a1) represents an alkylene group, a cycloalkylene group, an arylene group, —COO—, or a group of a combination of these groups.

[4]

The transfer film according to [2],
in which the repeating unit represented by Formula (a1) has a repeating unit represented by Formula (a1-1) described later.

[5]

The transfer film according to any one of [1] to [4],
in which the compound β is a compound B having, as the structure b0, a structure b capable of accepting an electron from the carboxy group in a photoexcited state.

[6]

The transfer film according to any one of [1] to [5],
in which the compound β is a compound B having, as the structure b0, a structure b capable of accepting an electron from the carboxy group in a photoexcited state, and
a total number of the structures b included in the compound B is 5 mol % or more with respect to a total number of the carboxy groups included in the polymer A.

[7]

The transfer film according to any one of [1] to [6],
in which the compound β is a nitrogen-containing aromatic compound.

[8]

The transfer film according to any one of [1] to [7],
in which the compound β is a nitrogen-containing aromatic compound having a substituent.

[9]

The transfer film according to any one of [1] to [8], in which a molar absorption coefficient ε₃₆₅ of the compound β at a wavelength of 365 nm is 1×10³ (cm·mol/L)⁻¹ or less.

[10]

The transfer film according to any one of [1] to [9],
in which a ratio of a molar absorption coefficient ε₃₆₅ of the compound β at a wavelength of 365 nm to a molar absorption coefficient ε₃₁₃ of the compound β at a wavelength of 313 nm is 3 or less.

[11]

The transfer film according to any one of [1] to [10],
in which a pKa of the compound β in a ground state is 2.0 or more.

[12]

The transfer film according to any one of [1] to [11],
in which a pKa of the compound β in a ground state is 9.0 or less.

[13]

The transfer film according to any one of [1] to [12],
in which the compound β includes one or more selected from the group consisting of isoquinoline and an isoquinoline derivative, quinoline and a quinoline derivative, quinazoline and a quinazoline derivative, quinoxaline and a quinoxaline derivative, and pyridine and a pyridine derivative.

[14]

The transfer film according to any one of [1] to [13],
in which the photosensitive layer further contains a polymerizable compound.

[15]

The transfer film according to any one of [1] to [14],
in which the photosensitive layer further contains a photopolymerization initiator.

[16]

The transfer film according to [15],
in which the photopolymerization initiator is one or more selected from the group consisting of an oxime ester compound and an aminoacetophenone compound.

[17]

The transfer film according to any one of [1] to [16],
in which the photosensitive layer further contains a polymerizable compound and a photopolymerization initiator, and
a content of the compound β is 1.5% to 7.5% by mass with respect to a total mass of the photosensitive layer.

[18]

A photosensitive composition comprising:
a polymer A; and
a compound β,
in which the polymer A includes one or more selected from the group consisting of a repeating unit represented by Formula (a1) described later and a repeating unit represented by Formula (a2) described later, and
the compound β has a structure b0 which reduces an amount of a carboxy group included in the polymer A by exposure.

[19]

The photosensitive composition according to [18],
in which the repeating unit represented by Formula (a1) has a repeating unit represented by Formula (a1-1) described later.

[20]

The photosensitive composition according to [18] or [19],
in which the compound β is a nitrogen-containing aromatic compound.

[21]

The photosensitive composition according to any one of [18] to [20], in which a molar absorption coefficient ε₃₆₅ of the compound β at a wavelength of 365 nm is 1×10³ (cm·mol/L)⁻¹ or less.

[22]

The photosensitive composition according to any one of [18] to [21],
in which a ratio of a molar absorption coefficient ε₃₆₅ of the compound β at a wavelength of 365 nm to a molar absorption coefficient ε₃₁₃ of the compound β at a wavelength of 313 nm is 3 or less.

[23]

The photosensitive composition according to any one of [18] to [22],
in which the compound 3 is a compound B having, as the structure b0, a structure b capable of accepting an electron from the carboxy group included in the polymer A in a photoexcited state.

[24]

The photosensitive composition according to any one of [18] to [23],
in which the compound 3 is a compound B having, as the structure b0, a structure b capable of accepting an electron from the carboxy group included in the polymer A in a photoexcited state, and
a total number of the structures b included in the compound B is 5 mol % or more with respect to a total number of the carboxy groups included in the polymer A.

According to the present invention, it is possible to provide a transfer film with which a film having excellent low moisture permeability and excellent scratch resistance can be formed. In addition, according to the present invention, it is possible to provide a photosensitive composition.

### BRIEF DESCRIPTION OF THE DRAWINGS

FIG. 1 is a schematic view showing an example of a layer configuration of a transfer film according to an embodiment.

### DESCRIPTION OF THE PREFERRED EMBODIMENTS

Hereinafter, the present invention will be described in detail.

In the present specification, a numerical range expressed using “to” means a range that includes the preceding and succeeding numerical values of “to” as a lower limit and an upper limit, respectively.

In addition, in a numerical range described in a stepwise manner in the present specification, an upper limit or a lower limit described in a certain numerical range may be replaced with an upper limit or a lower limit in another numerical range described in a stepwise manner. In addition, regarding the numerical range described in the present specification, an upper limit or a lower limit described in a numerical range may be replaced with a value described in Examples.

In addition, a term “step” in the present specification includes not only an independent step but also a step that cannot be clearly distinguished from other steps, as long as the intended purpose of the step is achieved.

In the present specification, “transparent” means that an average transmittance of visible light having a wavelength of 400 nm to 700 nm is 80% or more, preferably 90% or more. Therefore, for example, a “transparent resin layer” refers to a resin layer having an average transmittance of visible light having a wavelength of 400 to 700 nm is 80% or more.

In addition, the average transmittance of visible light is a value measured by using a spectrophotometer, and for example, can be measured by using a spectrophotometer U-3310 manufactured by Hitachi, Ltd.

In the present specification, “actinic ray” or “radiation” means, for example, a bright line spectrum of a mercury lamp such as g-rays, h-rays and i-rays, far ultraviolet rays typified by an excimer laser, extreme ultraviolet rays (EUV light), X-rays, electron beams (EB), or the like. In addition, in the present invention, light means the actinic ray or the radiation.

Unless otherwise specified, “exposure” in the present specification encompasses not only exposure by a mercury lamp, far ultraviolet rays typified by an excimer laser, extreme ultraviolet rays, X-rays, EUV light, or the like, but also exposure of drawing by corpuscular beams such as electron beams and ion beams.

In the present specification, a content ratio of each structural unit of a polymer is a molar ratio unless otherwise specified.

In addition, in the present specification, a refractive index is a value measured with an ellipsometer at a wavelength of 550 nm unless otherwise specified.

In the present specification, unless otherwise specified, a molecular weight in a case of a molecular weight distribution is a weight-average molecular weight.

In the present specification, a weight-average molecular weight of a resin is a weight-average molecular weight obtained by performing polystyrene conversion of a value measured by gel permeation chromatography (GPC).

In the present specification, “(meth)acrylic acid” is a concept including both acrylic acid and methacrylic acid, and “(meth)acryloyl group” is a concept including both an acryloyl group and a methacryloyl group.

In the present specification, unless otherwise specified, a thickness of a layer (film thickness) is an average thickness measured using a scanning electron microscope (SEM) for a thickness of 0.5 μm or more, and is an average thickness measured using a transmission electron microscope (TEM) for a thickness of less than 0.5 μm. The average thickness is an average thickness obtained by forming a section to be measured using an ultramicrotome, measuring thicknesses of any five points, and arithmetically averaging the values.

A bonding direction of a divalent linking group is not limited unless otherwise specified.

In a compound represented by “X—Y—Z”, in a case where Y is —COO—, Y may be —CO—O— or —O—CO—. In addition, the above-described compound may be “X—CO—O—Z” or “X—O—CO—Z”.

“Boiling point” means a boiling point at 1 atmospheric pressure.

[Transfer Film]

The transfer film is a transfer film including a temporary support and a photosensitive layer, in which the photosensitive layer contains a polymer A and a compound β, the polymer A has a repeating unit (a) having a carboxy group linked to a main chain by a linking group having 1 or more carbon atoms, and the compound β has a structure b0 which reduces an amount of the carboxy group included in the polymer A by exposure.

The transfer film can be suitably used for forming a film (pattern) on a base material. In a case where a film is formed on a base material using the transfer film, for example, the photosensitive layer of the transfer film is transferred to the base material on which the film (pattern) is to be formed, and the photosensitive layer transferred onto the base material is subjected to treatments such as exposure and development to form the film (pattern) on the base material.

Therefore, the transfer film according to the embodiment of the present invention is particularly suitable for use as a film for forming a protective film for a touch panel.

A mechanism by which the objects of the present invention can be achieved through such configurations is not always clear, but is considered to be as follows by the present inventors.

A feature point of the transfer film according to the embodiment of the present invention is, for example, that the photosensitive layer of the transfer film contains the polymer A and the compound B.

The compound β is a compound having the structure b0. The structure b0 can reduce the amount of the carboxy group included in the above-described polymer A by the exposure. More specifically, the structure b0 eliminates the carboxy group, which is an acid group, from the polymer A as carbon dioxide (decarboxylation). In addition, the above-described carboxy group on which the structure b0 acts may be an anion.

In a case where the structure b0 reduces the amount of the carboxy group included in the above-described polymer A, polarity of the portion is lowered. That is, in the photosensitive layer according to the present invention, polarity changes due to the elimination of the carboxy group in the polymer A at an exposed portion. Solubility in a developer changes at a place where the polarity changes, and in particular, solubility in the developer (alkali developer or organic solvent-based developer) changes in the exposed portion. For example, in the exposed portion, the solubility in an alkali developer decreases, and the solubility in an organic solvent-based developer is improved. Utilizing such a change in solubility in the exposed portion, with the transfer film according to the embodiment of the present invention, it is possible to form a positive or negative tone patterned film (hereinafter, also simply referred to as “pattern”).

The polymer A has a repeating unit which has a carboxy group, in which the carboxy group is bonded to a main chain through a linking group having 1 or more carbon atoms. As described above, since the compound β has a function of eliminating the carboxy group of the polymer A as carbon dioxide, in a film after exposing the photosensitive layer of the transfer film, the carboxy group is eliminated from the polymer A by the compound β.

In the film (pattern) obtained using the transfer film in the related art, since the carboxy group remains after the exposure, it may be difficult to sufficiently reduce moisture permeability. On the other hand, in the film (pattern) obtained using the transfer film according to the embodiment of the present invention, since the carboxy group, which is a hydrophilic group, is eliminated from the polymer A by the compound β, moisture permeability of the film after the exposure is low, and it is presumed that the moisture permeability is excellent.

In addition, in the case of the transfer film according to the embodiment of the present invention, since a group derived from the linking group having 1 or more carbon atoms remains even in a case of being decarboxylated, reduction in hardness of the film after the exposure can be suppressed, and it is presumed that scratch resistance is excellent.

Hereinafter, the fact that at least one of the moisture permeability or scratch resistance of the transfer film is more excellent is also referred to as that the effect of the present invention is more excellent.

Hereinafter, the transfer film will be described in detail.

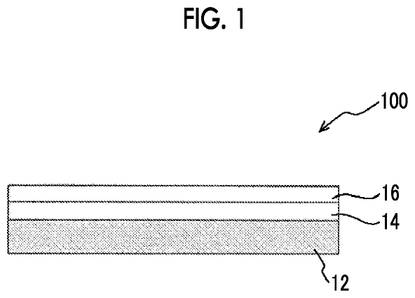

FIG. 1 is a schematic cross-sectional view showing an example of an embodiment of the transfer film.

A transfer film 100 shown in FIG. 1 is a laminate in which a temporary support 12, a photosensitive layer 14, and a cover film 16 are laminated in this order. The cover film 16 may or may not be provided.

<Temporary Support>

The transfer film includes a temporary support.

The temporary support is a support which supports the photosensitive layer and can be peeled off from the photosensitive layer.

From the viewpoint that the photosensitive layer can be exposed through the temporary support in a case where the photosensitive layer is exposed in a patterned manner, the temporary support preferably has light-transmitting property.

The “has light-transmitting property” means that a transmittance of light having a main wavelength used for exposure (may be pattern exposure or entire exposure) is 50% or more. From the viewpoint of more excellent exposure sensitivity, a transmittance of the light having a main wavelength used for the exposure is preferably 60% or more, and more preferably 70% or more.

More specifically, any of transmittances at a wavelength of 313 nm, at a wavelength of 365 nm, at a wavelength of 405 nm, and at a wavelength of 436 nm is preferably 60% or more, more preferably 70% or more, still more preferably 80% or more, and most preferably 90% or more. The upper limit is preferably 100% or less. Examples of a preferred specific value of the transmittance include 87%, 92%, and 98%.

Examples of a method for measuring the transmittance include a measuring method using MCPD Series (manufactured by OTSUKA ELECTRONICS Co., Ltd.).

From the viewpoint of further improving handleability, it is preferable that the temporary support includes a layer containing particles on a surface of the temporary support opposite to the photosensitive layer side.

The above-described layer containing particles preferably contains 1 particle/mm² or more of particles having a diameter of 0.5 to 5 μm, and more preferably contains 1 to 50 particles/mm² of particles having a diameter of 0.5 to 5 μm.

From the viewpoint of strength as a support, flexibility required for bonding to a substrate for forming a circuit wiring, and light-transmitting property required in a first exposing step, a thickness of the temporary support can be appropriately selected according to a material. Specifically, from the viewpoint of ease of handling and excellent general-purpose properties, the thickness of the temporary support is preferably 5 to 200 μm and more preferably 10 to 150 μm.

Examples of the temporary support include a glass substrate, a resin film, and paper, and from the viewpoint of more excellent strength and flexibility, a resin film is preferable.

Examples of the resin film include a polyethylene terephthalate (PET) film, a cellulose triacetate film, a polystyrene film, and a polycarbonate film, and a biaxial stretching polyethylene terephthalate film is preferable.

The temporary support may be a recycled product. Examples of the recycled product include films obtained by washing used films and the like, making the used films and the like into chips, and using the chips as a material. Specific examples of the recycled product include Ecouse series manufactured by Toray Industries, Inc.

Examples of the temporary support include paragraphs [0017] and [0018] of JP2014-085643A, paragraphs [0019] to [0026] of JP2016-027363A, paragraphs [0041] to [0057] of WO2012/081680A1, and paragraphs [0029] to [0040] of WO2018/179370A1, the contents of which are incorporated in the present specification.

Examples of the temporary support also include COSMOSHINE (registered trademark) A4100, COSMOSHINE (registered trademark) A4160, and COSMOSHINE (registered trademark) A4300, COSMOSHINE (registered trademark) A4360 (all of which are manufactured by TOYOBO Co., Ltd.); and LUMIRROR (registered trademark) 16FB40, 16QS62, and 16KS40 (all of which are manufactured by Toray Industries, Inc.). Specifically, as the temporary support, a biaxial stretching polyethylene terephthalate film having a thickness of 16 μm, a biaxial stretching polyethylene terephthalate film having a thickness of 12 μm, or a biaxial stretching polyethylene terephthalate film having a thickness of 9 μm is preferable.

<Photosensitive Layer>

The transfer film includes a photosensitive layer.

The photosensitive layer is a layer formed of a photosensitive composition described later.

It is preferable that the photosensitive layer is substantially a layer consisting of only a solid content component of the photosensitive composition. That is, it is preferable that the photosensitive composition constituting the photosensitive layer contain a solid content component (component other than a solvent) which can be contained in the photosensitive composition, in a content of each component contained in the photosensitive composition described later.

In a case where a photosensitive composition containing a solvent is applied and dried to form the photosensitive layer, the photosensitive layer may contain the solvent because the solvent remains in the photosensitive layer even after drying.

The photosensitive layer contains a polymer A and a compound 3. The polymer A and the compound β will be described in detail later. The photosensitive layer may contain a material other than the polymer A and the compound β. Examples of other materials include a material which may be contained in the photosensitive composition described later (for example, a polymerizable compound, a photopolymerization initiator, a surfactant, and the like).

A suitable numerical range of the content of each component in the photosensitive layer is the same as a suitable range in which “content (% by mass) of each component with respect to the total solid content of the photosensitive composition” described later is read as “content (% by mass) of each component with respect to the total mass of the photosensitive layer”. Therefore, for example, the description of “content of the compound A in the photosensitive composition is preferably 25% to 100% by mass with respect to the total solid content of the photosensitive composition” is read as “content of the compound A in the photosensitive layer is preferably 25% to 100% by mass with respect to the total mass of the photosensitive layer”.

In the photosensitive layer, a content of the carboxy group in the photosensitive layer is reduced by irradiation with actinic ray or radiation, with respect to the content of the carboxy group in the photosensitive layer before the irradiation.

A reduction rate of the content of the carboxy group in the photosensitive layer by the irradiation with actinic ray or radiation is preferably 5 mol % or more, more preferably 10 mol % or more, still more preferably 20 mol % or more, even more preferably 31 mol % or more, particularly preferably 40 mol % or more, more particularly preferably 51 mol % or more, and most preferably 71 mol % or more with respect to the content of the carboxy group in the photosensitive layer before the irradiation. The upper limit is preferably 100 mol % or less with respect to the content of the carboxy group in the photosensitive layer before the irradiation.

The reduction rate of the content of the carboxy group derived from the polymer A in the photosensitive layer can be calculated by measuring the amount of the carboxy group in the photosensitive layer before and after exposure. In a case of measuring the amount of the carboxy group in the photosensitive layer before the exposure, for example, the amount thereof can be analyzed and quantified by potentiometric titration. In addition, in a case of measuring the amount of the carboxy group in the photosensitive layer after the exposure, the hydrogen atom of the carboxy group is substituted with a metal ion such as lithium, and the amount thereof can be calculated by analyzing and quantifying the amount of this metal ion by inductively coupled plasma optical emission spectrometer (ICP-OES).

In addition, the reduction rate of the content of the carboxy group derived from the polymer A in the photosensitive layer can also be calculated by measuring an infrared (IR) spectrum of the photosensitive layer before and after the exposure and measuring a reduction rate of a peak derived from the carboxy group. The reduction rate of the content of the carboxy group can be calculated by measuring a reduction rate of a peak of C═O stretching and contracting (peak of 1710 cm¹) of the carboxy group.

An average thickness of the photosensitive layer is preferably 0.5 to 20 μm.

In a case where the average thickness of the photosensitive layer is 20 μm or less, resolution of the pattern is excellent. In a case where the average thickness of the photosensitive layer is 0.5 μm or more, pattern linearity is excellent. The average thickness of the photosensitive layer is more preferably 0.8 to 15 μm and still more preferably 1.0 to 10 μm.

Specifically, the average thickness of the photosensitive layer is preferably 3.0 μm, 4.0 μm, 5.0 μm, or 8.0 μm.

From the viewpoint of more excellent pattern forming ability and/or viewpoint that the moisture permeability of the pattern to be formed is further lowered, a transmittance of the photosensitive layer at a wavelength of 365 nm (transmittance to light having a wavelength of 365 nm) is preferably 20% or more, more preferably 50% or more, and still more preferably 65% or more. The upper limit is preferably 100% or less.

From the viewpoint of more excellent pattern forming ability and/or viewpoint that the moisture permeability of the pattern to be formed is further lowered, a ratio of the transmittance of the photosensitive layer at 365 nm (transmittance to light having a wavelength of 365 nm) to a transmittance of the photosensitive layer at 313 nm (transmittance to light having a wavelength of 313 nm) (transmittance of photosensitive layer at 365 nm/transmittance of photosensitive layer at 313 nm) is preferably 1 or more and more preferably 1.5 or more. The upper limit is preferably 1000 or less.

A visible light transmittance of the photosensitive layer at a thickness of approximately 1.0 μm is preferably 80% or more, more preferably 90% or more, and still more preferably 95% or more. The upper limit is preferably less than 100%. Specifically, the visible light transmittance of the photosensitive layer at a thickness of approximately 1.0 μm is preferably 87%, 92%, or 98%. As the above-described visible light transmittance, it is preferable that an average transmittance at a wavelength of 400 to 800 nm, the minimum value of the transmittance at a wavelength of 400 to 800 nm, and a transmittance at a wavelength of 400 nm all satisfy the above.

From the viewpoint of suppressing residue during development, a dissolution rate of the photosensitive layer in a 1.0% by mass sodium carbonate aqueous solution is preferably 0.01 μm/sec or more, more preferably 0.10 μm/sec or more, and still more preferably 0.20 μm/sec or more. In addition, from the viewpoint of edge shape of the pattern, it is preferable to be 5.0 μm/sec or less. Specifically, the dissolution rate of the photosensitive layer in a 1.0% by mass sodium carbonate aqueous solution is preferably 1.8 μm/sec, 1.0 μm/sec, or 0.7 μm/sec.

The dissolution rate of the photosensitive layer in a 1.0% by mass sodium carbonate aqueous solution per unit time is measured by the following method.

A photosensitive layer within a thickness range of 1.0 to 10 μm formed on a glass substrate, from which a solvent has been sufficiently removed, is subjected to a shower development with a 1.0% by mass sodium carbonate aqueous solution at 25° C. until the photosensitive layer is dissolved completely. However, a shower development time is up to 2 minutes.

It is obtained by dividing the thickness of the photosensitive layer by the time required until the photosensitive layer is completely dissolved. In a case where the photosensitive layer is not dissolved completely in 2 minutes, the dissolution rate of the photosensitive layer is calculated in the same manner as above, from the amount of change in thickness up to 2 minutes.

For the above-described development, a shower nozzle of ¼ MiNJJX030PP (manufactured by H.IKEUCHI Co., Ltd.) is used, and a spraying pressure of the shower is set to 0.08 MPa and a shower flow rate per unit time is set to 1,800 mL/min.

From the viewpoint of pattern formability, the number of foreign substances having a diameter of 1.0 μm or more in the photosensitive layer is preferably 10 pieces/mm² or less, and more preferably 5 pieces/mm² or less.

Specifically, the number of foreign substances having a diameter of 1.0 μm or more in the photosensitive layer is preferably 0 pieces/mm², 1 piece/mm², 4 pieces/mm², or 8 pieces/mm².

The number of foreign substances is measured by the following procedure.

Any 5 1 mm×1 mm regions on a surface of the photosensitive layer are visually observed from a normal direction of the surface of the photosensitive layer with an optical microscope, the number of foreign substances having a diameter of 1.0 μm or more in each region is measured, and the values are arithmetically averaged to calculate the number of foreign substances.

From the viewpoint of suppressing generation of aggregates during development, a haze of a solution obtained by dissolving 1.0 cm³ of the photosensitive layer in 1.0 L of a 1.0% by mass sodium carbonate aqueous solution at a liquid temperature of 30° C. is preferably 60% or less, more preferably 30% or less, still more preferably 10% or less, and particularly preferably 1% or less. Specifically, the haze is preferably 0.4%, 1.0%, 9%, or 24%.

The haze is measured by the following procedure.

A 1.0% by mass sodium carbonate aqueous solution is prepared, and a liquid temperature is adjusted to 30° C. 1.0 cm³ of the photosensitive layer is added to 1.0 L of the obtained sodium carbonate aqueous solution. The solution is stirred at 30° C. for 4 hours, being careful not to mix air bubbles. After stirring, the haze of the solution in which the photosensitive layer is dissolved is measured. The haze is measured using a haze meter (product name “NDH4000”, manufactured by Nippon Denshoku Industries Co., Ltd.), a liquid measuring unit, and a liquid measuring cell having an optical path length of 20 mm.

The photosensitive layer is preferably achromatic.

Specifically, in CIE1976 (L*, a*, b*) color space of the total reflection (incidence angle: 8°, light source: D-65 (visual field: 2°)), an L* value is preferably 10 to 90, an a* value is preferably −1.0 to 1.0, and an b* value is preferably −1.0 to 1.0.

Each value in the CIE1976 (L*, a*, b*) color space can be measured by a known method.

(Method for Forming Photosensitive Layer)

Examples of a method for forming the photosensitive layer include a known forming method.

Specific examples thereof include a method of preparing a photosensitive composition containing each solid content component (component other than a solvent) described later and a solvent, and then applying and drying the photosensitive composition.

The method of preparing the photosensitive composition containing a solvent may be a method of preparing the photosensitive composition by dissolving each solid content component in advance in the solvent to prepare a solution, and then mixing the obtained solution in a predetermined proportion.

Examples of a method of applying and drying the photosensitive composition containing a solvent include a method of applying the photosensitive composition containing a solvent onto the temporary support or the cover film, and then drying the photosensitive composition containing a solvent.

Examples of the applying method include known methods such as a slit coating, a spin coating, a curtain coating, and an inkjet coating.

The above-described photosensitive composition containing a solvent is preferably filtered using a filter having a pore diameter of 0.2 to 30 μm, or the like.

In addition, in a case where a layer of high refractive index and/or other layers, which are described later, are formed on the temporary support or the cover film, the photosensitive layer may be formed on the above-described layer of high refractive index and/or other layers.

<Layer of High Refractive Index>

The transfer film preferably includes a layer of high refractive index.

The layer of high refractive index is preferably disposed adjacent to the photosensitive layer, and is also preferably disposed on a side of the photosensitive layer opposite to the temporary support side.

The layer of high refractive index is not particularly limited as long as it is a layer having a refractive index of 1.50 or more.

The refractive index of the layer of high refractive index is 1.50, preferably 1.55 or more and more preferably 1.60 or more. The upper limit is preferably 2.10 or less, more preferably 1.85 or less, still more preferably 1.78 or less, and particularly preferably 1.74 or less. In addition, it is preferable that the refractive index of the layer of high refractive index is higher than the refractive index of the photosensitive layer.

The layer of high refractive index may have photocuring properties (photosensitivity) or thermosetting properties, or may have both photocuring properties and thermosetting properties.

In a case where the layer of high refractive index has photosensitivity, it is possible to collectively pattern the photosensitive layer and the layer of high refractive index transferred onto the base material by photolithography at one time, after the transferring.

The layer of high refractive index preferably has alkali solubility (for example, solubility with respect to weak alkali aqueous solution). In addition, the layer of high refractive index is preferably a transparent layer.

A thickness of the layer of high refractive index is preferably 500 nm or less, more preferably 110 nm or less, and still more preferably 100 nm or less. The lower limit is preferably 20 nm or more, more preferably 55 nm or more, still more preferably 60 nm or more, and particularly preferably 70 nm or more.

The layer of high refractive index may be disposed between a transparent electrode pattern and the photosensitive layer after the transferring, and a laminate including the transparent electrode pattern, the layer of high refractive index, and the photosensitive layer may be formed. In this case, by reducing a difference in refractive index between the transparent electrode pattern and the layer of high refractive index and a difference in refractive index between the layer of high refractive index and the photosensitive layer, light reflection can be further reduced, and covering property of the transparent electrode pattern is further improved. Specifically, in the laminate including the transparent electrode pattern, the layer of high refractive index, and the photosensitive layer in this order, in a case of being observed from the transparent electrode pattern side, the transparent electrode pattern is less visible.

The refractive index of the layer of high refractive index is preferably adjusted in accordance with the refractive index of the transparent electrode pattern.

For example, in a case where the refractive index of the transparent electrode pattern formed of an oxide of In and Sn (Indium Tin Oxide; ITO) is in a range of 1.8 to 2.0, the refractive index of the layer of high refractive index is preferably 1.60 or more. The upper limit is preferably 2.10 or less, more preferably 1.85 or less, still more preferably 1.78 or less, and particularly preferably 1.74 or less.

In a case where the refractive index of the transparent electrode pattern formed of an oxide of In and Zn (Indium Zinc Oxide; IZO) is more than 2.0, the refractive index of the layer of high refractive index is preferably 1.70 to 1.85.

Examples of a method for controlling the refractive index of the layer of high refractive index include a method using a resin having a predetermined refractive index alone, a method using a resin and particles, and a method using a composite body of a metal salt and a resin.

Examples of the particles include known inorganic particles such as metal oxide particles and metal particles. The metal of the metal oxide particles and the metal particles also includes semimetal such as B, Si, Ge, As, Sb, or Te.

From the viewpoint of transparency, an average primary particle diameter of the particles is preferably 1 to 200 nm, and more preferably 3 to 80 nm.

The average primary particle diameter of the particles is calculated by measuring particle diameters of 200 random particles using an electron microscope and arithmetically averaging the measurement result. In a case where the shape of the particle is not a spherical shape, the longest side is set as the particle diameter.

As the metal oxide particles, one or more selected from the group consisting of zirconium oxide particles (ZrO₂ particles), niobium pentoxide particles (Nb₂O₅ particles), titanium oxide particles (TiO₂ particles), silicon dioxide particles (SiO₂ particles), and composite particles combining these particles are preferable; and from the viewpoint that the refractive index of the layer of high refractive index can be easily adjusted to 1.6 or more, one or more selected from the group consisting of zirconium oxide particles and titanium oxide particles are more preferable.

The particles may be contained one kind alone, or may be contained two or more kinds thereof.

From the viewpoint that covering property of an object to be covered, such as the electrode pattern, and visibility of the object to be covered can be improved, a content of the particles is preferably 1% to 95% by mass, more preferably 20% to 95% by mass, and still more preferably 40% to 95% by mass with respect to the total mass of the layer of high refractive index.

In a case where the titanium oxide particles or the zirconium oxide particles are used as the metal oxide particles, a content of the titanium oxide particles or the zirconium oxide particles is preferably 1% to 95% by mass, more preferably 20% to 95% by mass, and still more preferably 40% to 85% by mass with respect to the total mass of the layer of high refractive index.

Examples of the metal oxide particles include calcined zirconium oxide particles (ZRPGM15WT %-F04, ZRPGM15WT %-F74, ZRPGM15WT %-F75, ZRPGM15WT %-F76, and the like; manufactured by CIK-Nano Tek.), and zirconium oxide particles (NanoUse OZ-S30M, NanoUse OZ—S30K, and the like; manufactured by Nissan Chemical Corporation).

The layer of high refractive index preferably contains one or more selected from the group consisting of inorganic particles having a high refractive index, a resin having a high refractive index, and a polymerizable compound having a high refractive index.

A refractive index in the inorganic particles having a high refractive index, the resin having a high refractive index, and the polymerizable compound having a high refractive index is preferably 1.50 or more, more preferably 1.55 or more, and still more preferably 1.60 or more. The upper limit is preferably 2.10 or less, more preferably 1.85 or less, still more preferably 1.78 or less, and particularly preferably 1.74 or less.

The layer of high refractive index preferably contains a polymer, a polymerizable compound, and particles.

Examples of the components contained in the layer of high refractive index include components of a curable transparent resin layer, described in paragraphs [0019] to [0040] and [0144] to [0150] of JP2014-108541A, components of a transparent layer, described in paragraphs [0024] to [0035] and [0110] to [0112] of JP2014-010814A, and components of a composition having an ammonium salt, described in paragraphs [0034] to [0056] of WO2016/009980A.

The layer of high refractive index also preferably contains a surfactant.

Examples of the surfactant include a surfactant which can be contained in the photosensitive composition described later.

The layer of high refractive index also preferably contains a metal oxidation inhibitor.

In a case where the layer of high refractive index contains a metal oxidation inhibitor, during transferring the layer of high refractive index onto the base material, a member that is in direct contact with the layer of high refractive index (for example, a conductive member formed on the base material) can be surface-treated. The above-described surface treatment can impart a metal oxide inhibiting function (protection properties) with respect to the member which is in direct contact with the layer of high refractive index.

The metal oxidation inhibitor is a compound different from the compound 3.

As the metal oxidation inhibitor, a compound having an aromatic ring including a nitrogen atom (nitrogen-containing aromatic compound) is preferable, and a compound having a 5-membered heteroaromatic ring having a nitrogen atom as a ring member atom is more preferable. The nitrogen-containing aromatic compound may further have a substituent.

As the nitrogen-containing aromatic compound, an imidazole ring, a triazole ring, a tetrazole ring, a thiazole ring, a thiadiazole ring, or a fused ring of any one of these rings and another aromatic ring is preferable, and an imidazole ring, a triazole ring, a tetrazole ring, or a fused ring of any one of these rings and another aromatic ring is more preferable.

Another aromatic ring may be a homocyclic ring or a heterocyclic ring.

As another aromatic ring, a homocyclic ring is preferable, a benzene ring or a naphthalene ring is more preferable, and a benzene ring is still more preferable.

As the metal oxidation inhibitor, imidazole, benzimidazole, tetrazole, 5-amino-1H-tetrazole, mercaptothiadiazole, or benzotriazole is preferable, and imidazole, benzimidazole, 5-amino-1H-tetrazole, or benzotriazole is more preferable.

Examples of a commercially available product of the metal oxidation inhibitor include BT120 (benzotriazole, manufactured by JOHOKU CHEMICAL CO., LTD.).

In a case where the layer of high refractive index contains a metal oxidation inhibitor, a content of the metal oxidation inhibitor is preferably 0.1% to 20% by mass, more preferably 0.5% to 10% by mass, and still more preferably 1% to 5% by mass with respect to the total mass of the layer of high refractive index.

The layer of high refractive index may contain a component other than the above-described components.

Examples of other components include other components which can be contained in the photosensitive composition described later.

(Method for Forming Layer of High Refractive Index)

Examples of a method for forming the layer of high refractive index include a known forming method.

Specific examples thereof include a method in which a composition for forming the layer of high refractive index, containing an aqueous solvent, is applied onto the photosensitive layer which has been formed on the temporary support, and the composition is dried as necessary.

The composition for forming the layer of high refractive index can contain each component of the above-described layer of high refractive index.

The composition for forming the layer of high refractive index preferably contains a polymer, a polymerizable compound, particles, and an aqueous solvent.

As the composition for forming the layer of high refractive index, a composition having an ammonium salt, described in paragraphs [0034] to [0056] of WO2016/009980A, is also preferable.

The layer of high refractive index is preferably achromatic.

Specifically, in CIE1976 (L*, a*, b*) color space of the total reflection (incidence angle: 8°, light source: D-65 (visual field: 2°)), an L* value is preferably 10 to 90, an a* value is preferably −1.0 to 1.0, and an b* value is preferably −1.0 to 1.0.

Each value in the CIE1976 (L*, a*, b*) color space can be measured by a known method.

<Cover Film>

The transfer film may include a cover film on a side of the photosensitive layer opposite to the temporary support side.

In a case where the transfer film includes the layer of high refractive index, it is preferable that the cover film is disposed on a side of the layer of high refractive index, opposite to the temporary support side. For example, it is preferable that “temporary support/photosensitive layer/layer of high refractive index/cover film” are laminated in this order.

The cover film preferably has 5 pieces/m² or less of the number of fisheyes with a diameter of 80 μm or more. The lower limit is preferably 0 piece/m² or more.

The “fisheye” means that, in a case where a material is hot-melted, kneaded, extruded, biaxially stretched, cast and/or the like to produce a film, foreign substances, undissolved substances, oxidatively deteriorated substances, and/or the like of the material are incorporated into the film.

The number of particles having a diameter of 3 μm or more included in the cover film is preferably 30 particles/mm² or less, more preferably 10 particles/mm² or less, and still more preferably 5 particles/mm² or less. The lower limit is preferably 0 particles/mm² or more.

Within the above-described range, it is possible to suppress defects caused by ruggedness due to the particles contained in the cover film being transferred to the photosensitive layer.

An arithmetic average roughness Ra of a surface of the cover film is preferably 0.01 μm or more, more preferably 0.02 μm or more, and still more preferably 0.03 μm or more. In a case where the transfer film has a long shape in the above-described range, take-up property in a case of winding the transfer film is excellent.

From the viewpoint of suppressing defects during transfer, the upper limit is preferably less than 0.50 μm, more preferably 0.40 μm or less, and still more preferably 0.30 μm or less.

The above-described arithmetic average roughness Ra can be measured by a known measuring method.

Examples of the cover film include a polyethylene terephthalate film, a polypropylene film, a polystyrene film, and a polycarbonate film.

Examples of the cover film also include paragraphs [0083] to [0087] and [0093] of

JP2006-259138A.

Examples of the cover film include ALPHAN (registered trademark) (FG-201, E-201F, and the like; manufactured by Oji F-Tex Co., Ltd.), Cerapeel (registered trademark) (25WZ; manufactured by TORAY ADVANCED FILM CO., LTD.), and LUMIRROR (registered trademark) (16QS62, 16KS40, and the like; manufactured by Toray Industries, Inc.). The cover film may be the same as the above-described temporary support.

<Other Layers>

The transfer film may include a layer other than the above-described layers.

Examples of other layers include a known interlayer and a known thermoplastic resin layer.

Examples of the thermoplastic resin layer include paragraphs [0189] to [0193] of JP2014-085643A, the contents of which are incorporated in the present specification.

Examples of layers other than the thermoplastic resin layer include paragraphs [0194] to [0196] of JP2014-085643A, the contents of which are incorporated in the present specification.

<Manufacturing Method of Transfer Film>

Examples of a manufacturing method of the transfer film include a known manufacturing method.

Specifically, it is preferable to include a step of forming a photosensitive layer by applying and drying a photosensitive composition containing a solvent on a temporary support, and it is more preferable to further include a step of disposing the cover film on the photosensitive layer after the step of forming the photosensitive layer.

In addition, after the step of forming the photosensitive layer, a step of forming the layer of high refractive index by applying and drying a composition for forming the layer of high refractive index may be included. In this case, after the step of forming the layer of high refractive index, it is preferable to further include a step of disposing a cover film on the layer of high refractive index.

The method of forming each layer is as described above.

[Photosensitive Composition]

The photosensitive composition contains a polymer A having a repeating unit (a) and a compound β having a structure b0 which reduces an amount of a carboxy group included in the polymer A by exposure.

The photosensitive composition is a material used for forming the photosensitive layer of the transfer film described above.

The “structure b0” is a structure which exhibits an action of reducing the amount of the carboxy group included in the polymer A in a case of being exposed. The structure b0 is preferably a structure which transitions from a ground state to an excited state by the exposure, and exhibits the action of reducing the carboxy group in the polymer A in the excited state.

As the structure b0, a structure (structure b) capable of accepting an electron from the carboxy group included in the polymer A in a photoexcited state by the exposure is preferable.

In a case where the structure b is exposed, acceptability of the electron increases, and the electron is transferred from the carboxy group of the polymer A. In a case of transferring the electron, the above-described carboxy group may be an anion.

In a case where the carboxy group transfers the electron to the structure b, the above-described carboxy group is unstable and to be carbon dioxide, and is eliminated. As a result, the amount of the carboxy group included in the polymer A is reduced by the exposure.

The compound β is preferably a compound B described later.

The compound B is a compound in which the structure b0 in the compound β is the structure b (structure capable of accepting an electron from the above-described carboxy group in a photoexcited state).

Hereinafter, with regard to an example of a polymer A having a repeating unit represented by Formula (a1) and quinoline, a presumed mechanism of an elimination process (decarboxylation process) in which the carboxy group is to be carbon dioxide and eliminated (presumed mechanism in which the content of the carboxy group derived from the polymer A can be reduced by exposure, starting from the structure b) will be described in detail.

As shown below, the carboxy group of the polymer A and a nitrogen atom of the quinoline form a hydrogen bond in the coexistence. In a case where the quinoline is exposed, acceptability of the electron increases, and the electron is transferred from the carboxy group (step 1: photoexcitation). In a case where the carboxy group included in the polymer A transfers the electron to the quinoline, the carboxy group is to be unstable and to be carbon dioxide, and is eliminated (step 2: decarboxylation reaction). After the above-described decarboxylation reaction, a radical is generated in a residue of the polymer, and a radical reaction proceeds. The radical reaction can occur between the residues of the polymer A, between the residue of the polymer A and any polymerizable compound (monomer (M)), or with a hydrogen atom in the atmosphere (step 3: polarity conversion-crosslinking-polymerization reaction). After the radical reaction is completed, the compound B can be regenerated and contribute to the decarboxylation process of the polymer A again (step 4: regeneration of compound B (catalyst)).

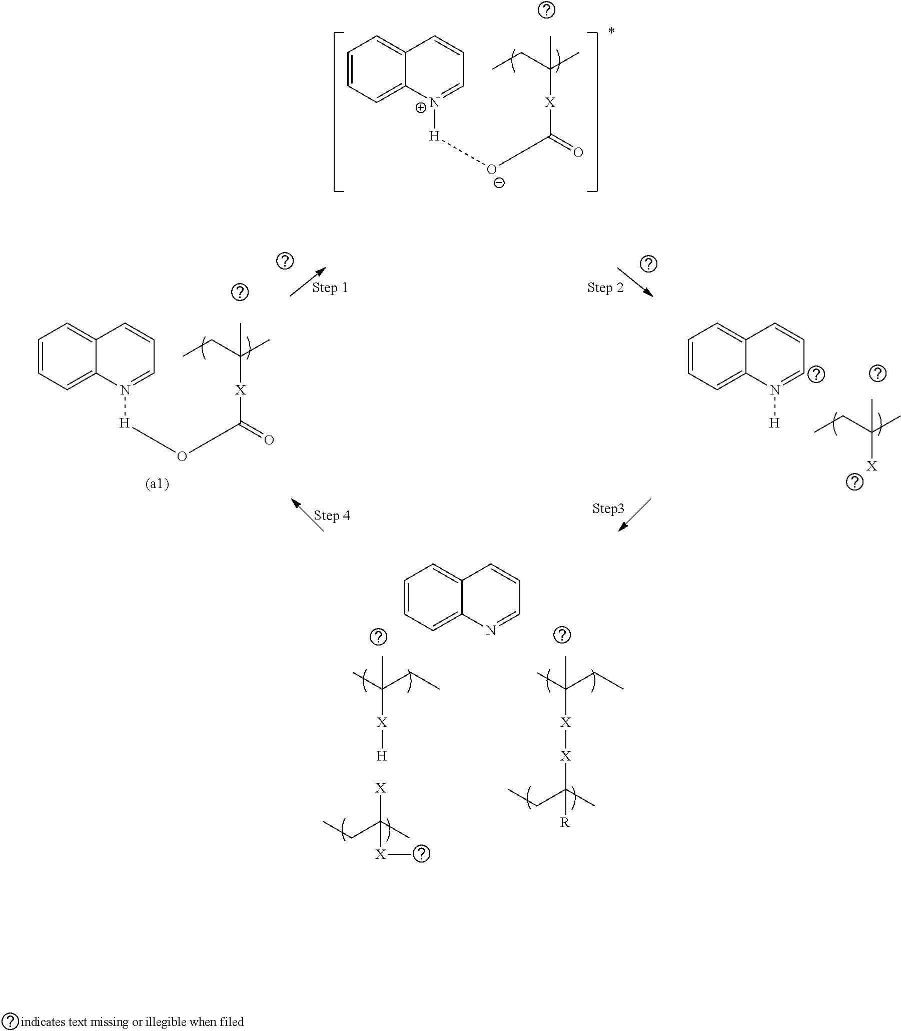

As a suitable aspect of the photosensitive composition according to the embodiment of the present invention, the following aspects 1 to 3 are preferable, and an aspect 3 is more preferable.

Aspect 1: the photosensitive composition does not contain a polymerizable compound and a photopolymerization initiator.

Aspect 2: the photosensitive composition further contains a polymerizable compound, and does not contain a photopolymerization initiator.

Aspect 3: the photosensitive composition further contains a polymerizable compound and a photopolymerization initiator.

The “photosensitive composition does not contain a polymerizable compound” means that the photosensitive composition does not substantially contain a polymerizable compound. Specifically, with respect to the total solid content of the photosensitive composition, a content of the polymerizable compound is less than 1% by mass, preferably 0% by mass or more and less than 1% by mass and more preferably 0% to 0.1% by mass.

The “photosensitive composition does not contain a photopolymerization initiator” means that the photosensitive composition does not substantially contain a photopolymerization initiator. Specifically, with respect to the total solid content of the photosensitive composition, a content of the photopolymerization initiator is less than 0.1% by mass, preferably 0% to 0.05% by mass and more preferably 0% to 0.01% by mass. The “solid content of the photosensitive composition” means a component in the photosensitive composition, other than a solvent. In addition, even in a liquid component, the liquid component is regarded as a solid content in a case where the liquid component is a component other than the solvent.

Hereinafter, components that can be contained in the photosensitive composition will be described in detail.

<Polymer A>

The photosensitive composition contains a polymer A.

The polymer A is a polymer which has a repeating unit (a) having a carboxy group linked to a main chain by a linking group having 1 or more carbon atoms.

All or a part of the carboxy group included in the polymer A may be either an anionic carboxy group (—COO—) or a non-anionic carboxy group (—COOH) in the photosensitive composition. That is, the notation of “carboxy group” is a concept including the anionic carboxy group (—COO—) and the non-anionic carboxy group (—COOH).

All or a part of the polymer A may be either an anionic polymer A or a non-anionic polymer A in the photosensitive composition. That is, the notation of “polymer A” is a concept including the anionic polymer A and the non-anionic polymer A.

The polymer A is preferably an alkali-soluble resin.

The “alkali-soluble” means that a dissolution rate obtained by the following method is 0.01 μm/sec or more.

A propylene glycol monomethyl ether acetate solution having a concentration of a target compound (for example, the polymer A) of 25% by mass is applied to a glass substrate, and then heated in an oven at 100° C. for 3 minutes to obtain a coating film of the target compound, having a thickness of 2.0 μm. The above-described coating film is immersed in a 1% by mass aqueous solution of sodium carbonate (liquid temperature: 30° C.), thereby obtaining the dissolution rate (μm/sec) of the above-described coating film.

In a case where the target compound is not dissolved in propylene glycol monomethyl ether acetate, the target compound is dissolved in an organic solvent (for example, tetrahydrofuran, toluene, ethanol, and the like) having a boiling point of lower than 200° C., other than propylene glycol monomethyl ether acetate.

From the viewpoint of developability, an acid value of the polymer A is preferably 60 to 300 mgKOH/g, more preferably 60 to 275 mgKOH/g, and still more preferably 70 to 250 mgKOH/g.

The acid value of the polymer A is a value measured by a titration method specified in JIS K0070 (1992).

A weight-average molecular weight (Mw) of the polymer A is preferably 5,000 or more and more preferably 8,000 or more. The upper limit is preferably 100,000 or less, and more preferably 50,000 or less.

A number-average molecular weight (Mn) of the polymer A is preferably 1,000 or more and more preferably 3,000 or more. The upper limit is preferably 100,000 or less, more preferably 50,000 or less, and still more preferably 30,000 or less.

(Repeating Unit (a))

The polymer A has a repeating unit (a).

The repeating unit (a) is a repeating unit having a carboxy group linked to a main chain by a linking group having 1 or more carbon atoms.

The “main chain” means the relatively longest bonding chain in a molecule of a polymer compound constituting the polymer. That is, the above-described carboxy group is a group in which a linking group having 1 or more carbon atoms and the above-described carboxy group are bonded to the main chain in this order, in which the linking group having 1 or more carbon atoms is provided between the main chain and the above-described carboxy group.

In addition, for example, a ring group directly bonded to the main chain, such as Y in Formula (a2) described later, corresponds to the linking group, and in a case where Y has 1 or more carbon atoms, Y corresponds to the above-described linking group having 1 or more carbon atoms.

The polymer A may further have an acid group other than the above-described carboxy group.

Examples of the acid group other than the above-described carboxy group include a phenolic hydroxyl group, a phosphoric acid group, and a sulfonic acid group.

It is preferable that the repeating unit (a) has one or more selected from the group consisting of a repeating unit represented by Formula (a1) and a repeating unit represented by Formula (a2), and it is more preferable that the repeating unit (a) has a repeating unit represented by Formula (a1-1).

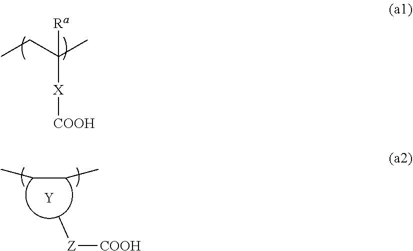

In Formula (a1), R^{a} represents a hydrogen atom or a substituent, and X represents a linking group having 1 or more carbon atoms.

In Formula (a2), Y represents a ring group, Z represents a single bond or a linking group, and at least one of Y or Z represents a group having 1 or more carbon atoms.

R^{a} represents a hydrogen atom or a substituent.

Examples of the above-described substituent include an alkyl group, an alkoxycarbonyl group, and a hydroxyalkyl group.

The above-described alkyl group may be linear or branched. The number of carbon atoms in the above-described alkyl group is preferably 1 to 5, and more preferably 1 to 3.

As an alkyl group constituting the above-described alkoxycarbonyl group and the above-described hydroxyalkyl group, the above-described alkyl group is preferable.

X represents a linking group having 1 or more carbon atoms.

Examples of the linking group having 1 or more carbon atoms include —CO—, —COO—, —NR^{NA}_(R^{NA} represents an alkyl group having 1 to 5 carbon atoms), a divalent hydrocarbon group, a linking group X1 selected from groups of a combination of these groups, and a linking group X2 formed from the linking group X1 and a linking group selected from —O—, —S—, —NH—, and a group of a combination of these groups.

As the linking group having 1 or more carbon atoms, an alkylene group, an arylene group, —COO—, an amide linking group, a carbonate linking group, a urethane linking group, a urea linking group, a linking group Y1 selected from groups of a combination of these groups, or a linking group Y2 formed from the linking group Y1 and a linking group selected from —O—, —S—, —NH—, and a group of a combination of these groups is preferable, and an alkylene group, a cycloalkylene group, an arylene group, —COO—, or a group of a combination of these groups is more preferable.

The above-described linking group having 1 or more carbon atoms may further have a substituent. Examples of the substituent include a hydroxyl group, an alkyl group, and a halogen atom.

The number of carbon atoms in the linking group having 1 or more carbon atoms is 1 or more, preferably 1 to 30, more preferably 1 to 10, and still more preferably 1 to 8.

The above-described hydrocarbon group may be linear, branched, or cyclic.

The number of carbon atoms in the above-described hydrocarbon group is preferably 1 to 30, more preferably 1 to 20, and still more preferably 1 to 10.

Examples of the above-described hydrocarbon group include arylene groups such as an alkylene group, a cycloalkylene group, an alkenylene group, and a phenylene group, and an alkylene group, a cycloalkylene group, or an arylene group is preferable.

The linking group having 1 or more carbon atoms is preferably an alkylene group A.

The alkylene group A is a linear alkylene group having 1 to 7 carbon atoms, which may have a substituent, and “—CH₂—CH₂—” in the alkylene group may be substituted with “—CO—O—” or “—CH═CH—”. In addition, in a case of having a plurality of substituents, two or more substituents may be bonded to each other to form a ring.

Examples of the above-described substituent include an alkyl group, an alkenylene group, an alkoxy group, an aryl group, a halogen atom, and a hydroxy group.

Specifically, in a case where the alkylene group A is “—CH₂—CH₂—CH₂—CH₂—CH₂—COOH”, it may be “—COO—CH₂—CH₂—CH₂—COOH” or “—CH═CH—CH₂—CH₂—CH₂—COOH”. In addition, as shown below, a substituent R¹ and a substituent R² in the alkylene group A may be bonded to each other to form a ring.

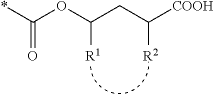

In addition, the alkylene group A is preferably a group represented by Formula (A).

*-L¹-L³-L²-COOH (A)

In Formula (A), L¹ represents a single bond or —CH₂—. L² represents —(CR^{a1}R^{a2})n-, a phenylene group which may have a substituent, a norbornane ring which may have a substituent, or a cyclohexane ring which may have a substituent. R^{a1} and R^{a2} each independently represent a hydrogen atom or a methyl group. n represents an integer of 1 to 3. L³ represents a single bond, a phenylene group which may have a substituent, *1-COO—*2, or *1-OCO-*2. *1 represents a bonding position to L¹. *2 represents a bonding position to L². * represents a bonding position.

A plurality of R^{a1}'s and a plurality of R^{a2}'s may be the same or different from each other.

In Formula (a2), Y represents a ring group.

In a case where Y is a ring group having 1 or more carbon atoms, Y corresponds the linking group having 1 or more carbon atoms, included in the polymer A.

The above-described ring may be a monocycle or a polycycle.

The above-described ring is preferably an alicyclic ring group. The number of carbon atoms in the alicyclic ring is preferably 1 or more, more preferably 1 to 30, still more preferably 3 to 20, and particularly more preferably 3 to 15. In other words, Y is preferably a ring group having 1 or more carbon atoms.

Two carbon atoms forming a bonding point between the main chain and the ring group represented by Y are not included in the number of carbon atoms in the ring group represented by Y. In other words, in Formula (a2), two carbon atoms constituting the main chain are not included in the number of carbon atoms in the ring group represented by Y.

The alicyclic ring may have a heteroatom.

As the heteroatom, a nitrogen atom, an oxygen atom, or a sulfur atom is preferable. A position where the heteroatom is introduced may be any of a ring member atom or a position other than the ring member atom. Specifically, a carbon atom in methylene constituting the ring of the alicyclic ring may be replaced with —O—, —CO—, —NR^{N}— (R^{N} represents a hydrogen atom or an alkyl group having 1 to 5 carbon atoms), or a group of a combination of these groups. In addition, examples of the position where the heteroatom is introduced, other than the ring member atom, include introduction into a substituent included in the alicyclic ring.

Examples of the alicyclic ring having a heteroatom include an imide ring such as a succinimide ring.

Examples of a ring constituting the alicyclic ring group include a cyclopentane ring, a cyclohexane ring, a dicyclopentane ring, an isobornane ring, an adamantane ring, a tricyclodecane ring, a tricyclodecene ring, norbornane ring, an isophorone ring, and a ring of a combination of these rings.

The alicyclic ring group may further have a substituent. The above-described substituent is preferably an alkyl group or an alkenyl group.

Z represents a single bond or a linking group.

Examples of the above-described linking group include the linking group having 1 or more carbon atoms, represented by X in Formula (a1), —O—, —S—, —NH—, and a group of a combination of these groups, and the linking group having 1 or more carbon atoms, represented by X, is preferable.

At least one of Y or Z represents a group having 1 or more carbon atoms.

It is preferable that both Y and Z represent a group having 1 or more carbon atoms.

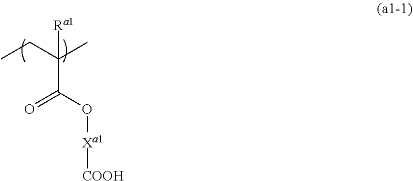

In Formula (a1-1), R^{a1} represents a hydrogen atom or a methyl group. X^{a1} represents a linking group.

Examples of X^{a1} include Z in Formula (a2).

As X^{a1}, the above-described linking group having 1 or more carbon atoms is preferable, and an alkylene group, an arylene group, —COO—, an amide linking group, a carbonate linking group, a urethane linking group, a urea linking group, or a group of a combination of these groups is more preferable, and an alkylene group, a cycloalkylene group, an arylene group, or a group of a combination of these groups is still more preferable.

Examples of the repeating unit (a) include the following repeating units.

In the following, R₁ and R₂ represent a hydrogen atom or a methyl group.

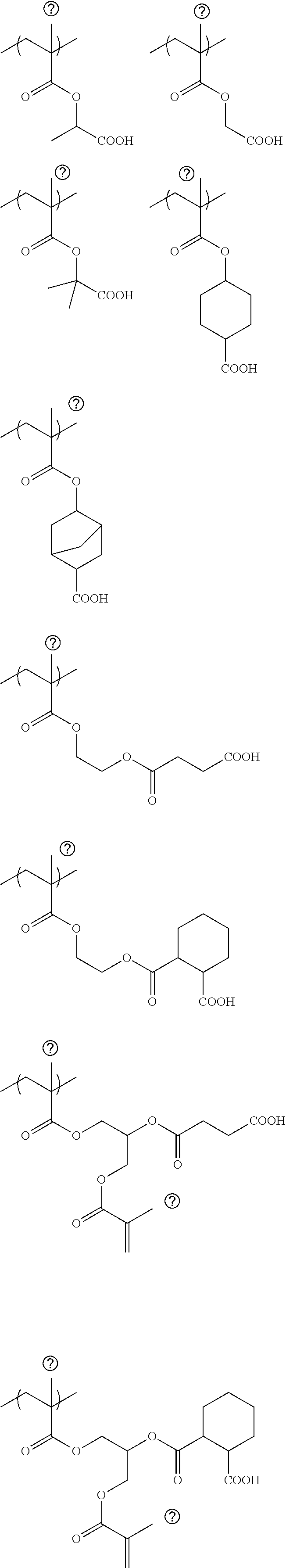

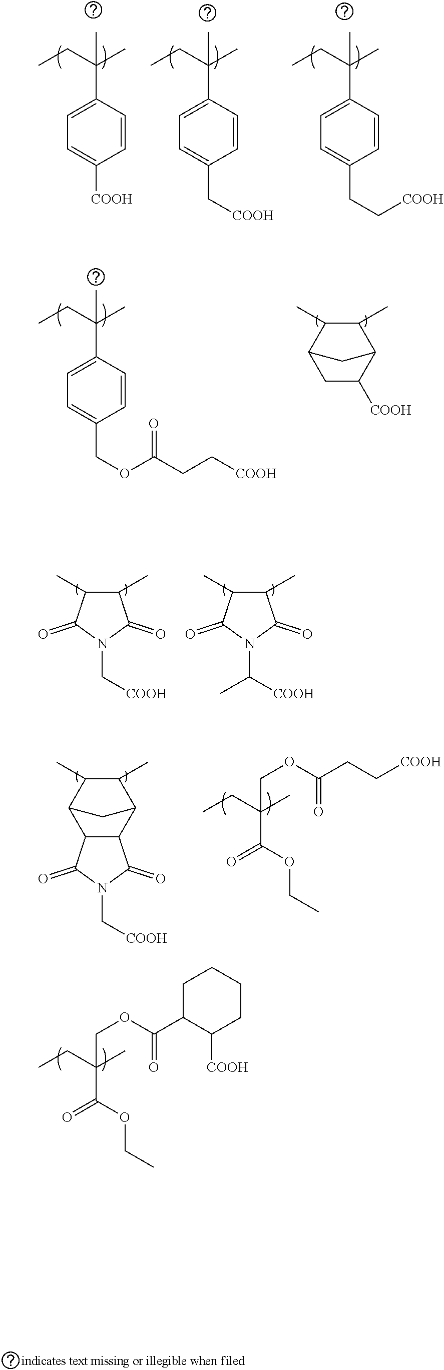

The repeating unit (a) may be used alone or in combination of two or more kinds thereof.

A content of the repeating unit (a) is preferably 1 to 90 mol %, more preferably 5 to 80 mol %, and still more preferably 10 to 70 mol % with respect to all repeating units of the polymer A.

The content of the repeating unit (a) is preferably 1% to 80% by mass, more preferably 10% to 70% by mass, and still more preferably 20% to 60% by mass with respect to all repeating units of the polymer A.

(Repeating Unit Having Polymerizable Group)

The polymer A may have a repeating unit having a polymerizable group.

The repeating unit having a polymerizable group is a repeating unit different from the above-described repeating unit.

Examples of the polymerizable group include an ethylenically unsaturated group (for example, a (meth)acryloyl group. a vinyl group, and a styryl group), and a cyclic ether group (for example, an epoxy group and an oxetanyl group), and an ethylenically unsaturated group is preferable and a (meth)acryloyl group is more preferable.

Examples of the repeating unit having a polymerizable group include a repeating unit represented by Formula (B).

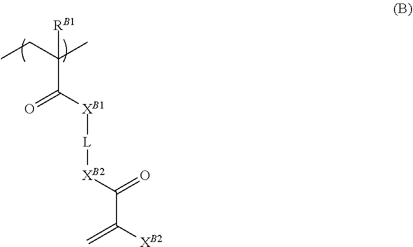

In Formula (B), X^{B1} and X^{B2} each independently represent —O— or —NR^{N}—. R^{N} represents a hydrogen atom or an alkyl group. L represents —COO—, an alkylene group, an arylene group, or a group of a combination of these groups. R^{B1} and R^{B2} each independently represent a hydrogen atom or an alkyl group.

X^{B1} and X^{B2} each independently represent —O— or —NR^{N}—. R^{N} represents a hydrogen atom or an alkyl group.

The above-described alkyl group may be linear or branched. The number of carbon atoms in the above-described alkyl group is preferably 1 to 5.

L represents —COO—, an alkylene group, an arylene group, or a group of a combination of these groups.

The above-described alkylene group may be linear or branched. The number of carbon atoms in the above-described alkylene group is preferably 1 to 5.

The above-described arylene group may be monocyclic or polycyclic. The number of carbon atoms in the above-described arylene group is preferably 6 to 15.

The above-described alkylene group and the above-described arylene group may further have a substituent. A hydroxyl group is preferable as the substituent.

Examples of the group in which the above-described groups are combined include —COO-alkylene group-, —COO-arylene group-, and -alkylene group-COO-alkylene group-.

R^{B1} and R^{B2} each independently represent a hydrogen atom or an alkyl group.

The above-described alkyl group may be linear or branched. The number of carbon atoms in the above-described alkyl group is preferably 1 to 5, and more preferably 1.

Examples of the repeating unit having a polymerizable group include the following repeating units.

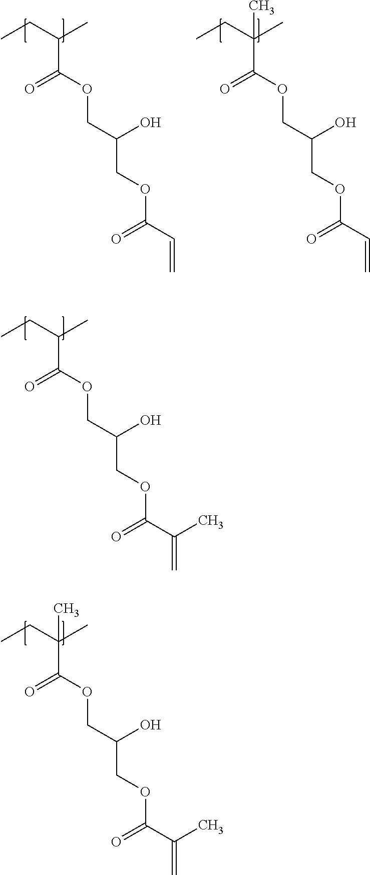

The repeating unit having a polymerizable group may be used alone or in combination of two or more kinds thereof.

In a case where the polymer A has the repeating unit having a polymerizable group, a content thereof is preferably 3 to 60 mol %, more preferably 5 to 40 mol %, and still more preferably 10 to 30 mol % with respect to all repeating units of the polymer A.

In addition, the content of the repeating unit having a polymerizable group is preferably 1% to 70% by mass, more preferably 5% to 50% by mass, and still more preferably 10% to 45% by mass with respect to all repeating units of the polymer A.

(Repeating Unit Having Aromatic Ring)

The polymer A may have a repeating unit having an aromatic ring.

The repeating unit having an aromatic ring is a repeating unit different from the above-described repeating units.

As the aromatic ring, an aromatic hydrocarbon ring is preferable.

Examples of the repeating unit having an aromatic ring include a repeating unit derived from (meth)acrylate having an aromatic ring, styrene, and a polymerizable styrene derivative.

Examples of the (meth)acrylate having an aromatic ring include benzyl (meth)acrylate, phenethyl (meth)acrylate, and phenoxyethyl (meth)acrylate.

Examples of the styrene and the polymerizable styrene derivative include methylstyrene, vinyltoluene, tert-butoxystyrene, acetoxystyrene, styrene dimer, and styrene trimer.

As the repeating unit having an aromatic ring, a repeating unit represented by Formula (C) is preferable.

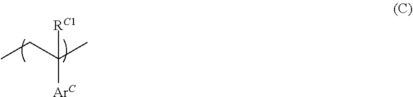

In Formula (C), R^{C1} represents a hydrogen atom, a halogen atom, or an alkyl group. Ar^{C} represents a phenyl group or a naphthyl group.

R^{C1} represents a hydrogen atom, a halogen atom, or an alkyl group.

The above-described alkyl group may be linear or branched. The number of carbon atoms in the above-described alkyl group is preferably 1 to 5, and more preferably 1.

Ar^{C} represents a phenyl group or a naphthyl group.

The above-described phenyl group and naphthyl group may have a substituent. Examples of the above-described substituent include an alkyl group, an alkoxy group, an aryl group, a halogen atom, and a hydroxy group.

Examples of the repeating unit having an aromatic ring include the following repeating units.

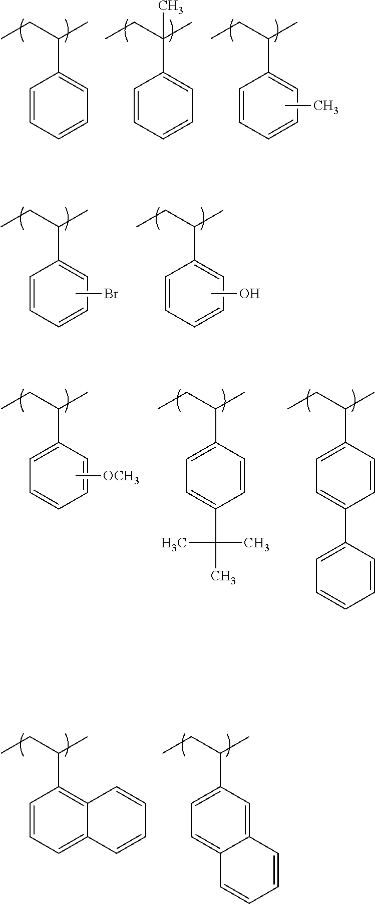

As the repeating unit having an aromatic ring, the following repeating unit is preferable.

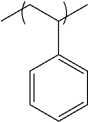

The repeating unit having an aromatic ring may be used alone or in combination of two or more kinds thereof.

In a case where the polymer A has the repeating unit having an aromatic ring, a content thereof is preferably 1 to 90 mol %, more preferably 5 to 85 mol %, and still more preferably 10 to 80 mol % with respect to all repeating units of the polymer A.

In addition, in a case where the polymer A has the repeating unit having an aromatic ring, the content thereof is preferably 1% to 90% by mass, more preferably 5% to 80% by mass, and still more preferably 10% to 70% by mass with respect to all repeating units of the polymer A.

(Repeating Unit Having Alicyclic Structure)

The polymer A may have a repeating unit having an alicyclic structure.

The repeating unit having an alicyclic structure is a repeating unit different from the above-described repeating units.

The alicyclic structure may be monocyclic or polycyclic.

Examples of an alicyclic ring constituting the alicyclic structure include a dicyclopentanyl ring, a dicyclopentenyl ring, an isobornyl ring, an adamantane ring, and a cyclohexyl ring.

Examples of a monomer from which the repeating unit having an alicyclic structure is derived include dicyclopentanyl (meth)acrylate, dicyclopentenyl (meth)acrylate, isobornyl (meth)acrylate, adamantyl (meth)acrylate, and cyclohexyl (meth)acrylate.

The repeating unit having an alicyclic structure may be used alone or in combination of two or more kinds thereof.

In a case where the polymer A includes the repeating unit having an alicyclic structure, a content thereof is preferably 3 to 70 mol %, more preferably 5 to 60 mol %, and still more preferably 10 to 55 mol % with respect to all repeating units of the polymer A.

In addition, the content of the repeating unit having an alicyclic structure in the polymer A is preferably 3% to 90% by mass, more preferably 5% to 70% by mass, and still more preferably 25% to 60% by mass with respect to all repeating units of the polymer A.

(Other Repeating Units)

The polymer A may have other repeating units in addition to the above-described repeating units.

Examples of the above-described other repeating units include a repeating unit having an acid group and a repeating unit derived from (meth)acrylic acid alkyl ester.

The repeating unit having an acid group is a repeating unit different from the above-described repeating unit (a). In other words, the repeating unit having an acid group is a repeating unit having a carboxy group directly bonded to the polymer main chain.

The repeating unit having an acid group is preferably a repeating unit derived from (meth)acrylic acid.

Examples of the above-described acid group include a phenolic hydroxyl group, a phosphoric acid group, and a sulfonic acid group.

The content of the repeating unit (a) is preferably 50 to 100 mol %, more preferably 70 to 100 mol %, and still more preferably 90 to 100 mol % with respect to the total moles of the repeating unit having an acid group and the repeating unit (a).

The content of the repeating unit (a) is preferably 50% to 100% by mass, more preferably 70% to 100% by mass, and still more preferably 90% to 100% by mass with respect to the total mass of the repeating unit having an acid group and the repeating unit (a).

An alkyl group in the (meth)acrylic acid alkyl ester may be linear or branched. The number of carbon atoms in the above-described alkyl group is preferably 1 to 50, and more preferably 1 to 10. The above-described alkyl group may further have a substituent. A hydroxy group is preferable as the substituent.

Examples of the (meth)acrylic acid alkyl ester include methyl (meth)acrylate, ethyl (meth)acrylate, butyl (meth)acrylate, and 2-ethylhexyl (meth)acrylate.

The other repeating units may be used alone or in combination of two or more kinds thereof.

In a case where the polymer A includes other repeating units, a content thereof is preferably 1 to 80 mol %, more preferably 5 to 70 mol %, and still more preferably 5 to 60 mol % with respect to all repeating units of the polymer A.

In addition, the content of the other repeating units in the polymer A is preferably 1% to 70% by mass, more preferably 5% to 60% by mass, and still more preferably 10% to 50% by mass with respect to all repeating units of the polymer A.

The polymer A may be used alone or in combination of two or more kinds thereof.

A content of the polymer A is preferably 25% by mass or more and less than 100% by mass with respect to the total solid content of the photosensitive composition.

In the photosensitive composition of the aspect 1, the content of the polymer A is preferably 40% to 98% by mass, more preferably 50% to 96% by mass, and still more preferably 60% to 93% by mass with respect to the total solid content of the photosensitive composition.

In the photosensitive composition of the aspect 2, the content of the polymer A is preferably 30% to 85% by mass and more preferably 45% to 75% by mass with respect to the total solid content of the photosensitive composition.

In the photosensitive composition of the aspect 3, the content of the polymer A is preferably 30% to 85% by mass and more preferably 45% to 75% by mass with respect to the total solid content of the photosensitive composition.

From the viewpoint of patterning properties and reliability, a content of a residual monomer of monomers used to produce each repeating unit in the polymer A is preferably 5,000 ppm by mass or less, more preferably 2,000 ppm by mass or less, and still more preferably 500 ppm by mass or less with respect to the total mass of the polymer A. The lower limit is preferably 1 ppm by mass or more, and more preferably 10 ppm by mass or more with respect to the total mass of the polymer A.

In addition, from the viewpoint of patterning properties and reliability, the content of the above-described residual monomer is preferably 3,000 ppm by mass or less, more preferably 600 ppm by mass or less, and still more preferably 100 ppm by mass or less with respect to the total solid content of the photosensitive composition. The lower limit is preferably 0.1 ppm by mass or more, and more preferably 1 ppm by mass or more with respect to the total solid content of the photosensitive composition.

It is preferable that a residual amount of monomers in a case of synthesizing the alkali-soluble resin by a polymer reaction is also within the above-described range. For example, in a case where glycidyl (meth)acrylate is reacted with a carboxylic acid side chain to synthesize the alkali-soluble resin, a content of the glycidyl (meth)acrylate is preferably within the above-described range.

Examples of a method for adjusting the content of the residual monomer include a method of selecting a monomer having a small content of impurities, a method of preventing impurities from being mixed during the synthesis of the polymer A, and a method of removing impurities by washing.

The content of the residual monomer can be measured by a known method such as liquid chromatography and gas chromatography.

<Compound β>

The photosensitive composition contains a compound β.

The compound β is a compound having a structure (structure b0) which reduces the amount of the carboxy group included in the polymer A by the exposure. The structure b0 is as described above.

As the structure b0, a structure (structure b) capable of accepting an electron from the carboxy group included in the polymer A in a photoexcited state is preferable. That is, the compound β is preferably a compound B having a structure (structure b) capable of accepting an electron from the carboxy group included in the polymer A in a photoexcited state.

The compound β reduces the amount of the carboxy group included in the polymer A by light irradiation. For example, the compound B, which is a suitable aspect of the compound β, is excited by light irradiation and accepts an electron from the carboxy group (preferably, anionized carboxy group) in the polymer A in the excited state. As a result, the carboxy group of the polymer A is to be a carboxy radical, and then the polymer A is decarboxylated.

Due to the action of the compound β (preferably, the compound B), it is considered that, in the exposed portion, the solubility of the polymer A in the developer changes (insolubilization in the alkali developer, or the like), and a pattern can be formed.

The structure b0 (preferably, the structure b) included in the compound β (preferably, the compound B) may be a structure constituting the entire compound β (preferably, the compound B) or a partial structure constituting a part of the compound β (preferably, the compound B).

Examples of the compound β (preferably, the compound B) include an aromatic compound.

The aromatic compound may have a substituent, and may have a heteroatom.

As the aromatic compound, a nitrogen-containing aromatic compound is preferable, and a nitrogen-containing aromatic compound having a substituent is more preferable.

The “aromatic compound” is a compound having one or more aromatic rings. The “nitrogen-containing aromatic compound” is a compound which a heteroaromatic ring having 1 or more (for example, 1 to 4) nitrogen atoms as a ring member atom.

The compound β (preferably, the compound B) may have 1 or 2 or more aromatic rings.

The aromatic ring in the compound β (preferably, the compound B) can be used as the above-described structure b capable of accepting an electron from the carboxy group included in the polymer A in a photoexcited state. The above-described aromatic ring may be an overall structure constituting the entire compound β (preferably, the compound B) or a partial structure constituting a part of the compound β (preferably, the compound B).

The above-described aromatic ring may be a monocycle or a polycycle, and is preferably a polycycle. For example, the polycyclic aromatic ring is an aromatic ring in which a plurality of (for example, 2 to 5) aromatic ring structures is fused, and at least one of the plurality of aromatic ring structures preferably has a heteroatom as a ring member atom.

The above-described aromatic ring may be a heteroaromatic ring.

As the heteroaromatic ring, a heteroaromatic ring having 1 or more (for example, 1 to 4) heteroatoms (for example, nitrogen atom, oxygen atom, sulfur atom, and the like) as a ring member atom is preferable, and a heteroaromatic ring having 1 or more (for example, 1 to 4) nitrogen atoms as a ring member atom is more preferable.

The number of ring member atoms in the above-described aromatic ring is preferably 5 to 15.

As the compound β, a compound which has a 6-membered heteroaromatic ring having a nitrogen atom as a ring member atom is preferable.

Examples of the above-described aromatic ring include monocyclic aromatic rings such as a pyridine ring, a pyrazine ring, a pyrimidine ring, and a triazine ring; aromatic rings in which two rings are fused, such as a quinoline ring, an isoquinoline ring, a quinoxaline ring, a quinazoline ring, a cinnoline ring, and a phthalazine ring; and aromatic rings in which three rings are fused, such as an acridine ring, a phenanthridine ring, a phenanthroline ring, and a phenazine ring.

The above-described aromatic ring may further have 1 or more (for example, 1 to 5) substituents.

Examples of the substituent include an alkyl group, an aryl group, a halogen atom, an acyl group, an alkoxycarbonyl group, an arylcarbonyl group, a carbamoyl group, a hydroxy group, a cyano group, an amino group, and a nitro group. In addition, in a case where the above-described aromatic ring has two or more substituents, a plurality of substituents may be bonded to each other to form a non-aromatic ring.

In addition, it is also preferable that the above-described aromatic ring is directly bonded to a carbonyl group to form an aromatic carbonyl group in the compound β (preferably, the compound B). It is also preferable that a plurality of aromatic rings is bonded through a carbonyl group.

It is also preferable that the above-described aromatic ring is bonded to an imide group to form an aromatic imide group in the compound β (preferably, the compound B). The imide group in the aromatic imide group may or may not form an imide ring together with the aromatic ring.

In a case where a plurality of aromatic rings (for example, 2 to 5 aromatic rings) forms a series of aromatic ring structures bonded with a structure selected from the group consisting of a single bond, a carbonyl group, and a multiple bond (for example, a vinylene group which may have a substituent, —C—C—, —N═N—, and the like), the series of entire aromatic ring structures are regarded as one structure b.

In addition, it is preferable that one or more of aromatic rings constituting the series of aromatic ring structures are the above-described heteroaromatic rings.

From the viewpoint that the effect of the present invention is more excellent, the compound β (preferably, the compound B) is preferably a compound satisfying 1 or more (for example, 1 to 4) of the following requirements (1) to (4). Among these, it is preferable that at least the requirement (2) is satisfied, and it is preferable that the heteroatom of the heteroaromatic ring has at least a nitrogen atom.
(1) the compound β (preferably, the compound B) has a polycyclic aromatic ring
(2) the compound β (preferably, the compound B) has a heteroaromatic ring
(3) the compound β (preferably, the compound B) has an aromatic carbonyl group
(4) the compound β (preferably, the compound B) has an aromatic imide group.

In addition, from the viewpoint of more excellent pattern forming ability and/or viewpoint that the moisture permeability of the pattern to be formed is further lowered, the compound β (preferably, the compound B) is preferably an aromatic compound having a substituent (compound having a substituent at a constituent atom of the aromatic ring included in the compound β (preferably, the compound B)), and more preferably a compound which satisfies 1 or more (for example, 1 to 4) of the above-described requirements (1) to (4) and further has a substituent.

As an introduction position of the substituent, for example, in a case where the compound β (preferably, the compound B) is quinoline or a quinoline derivative, from the viewpoint of more excellent pattern forming ability and/or viewpoint that the moisture permeability of the pattern to be formed is further lowered, it is preferable to have a substituent at at least a 2-position or a 4-position on the quinoline ring. In addition, for example, in a case where the compound β (preferably, the compound B) is isoquinoline or an isoquinoline derivative, from the viewpoint of more excellent pattern forming ability and/or viewpoint that the moisture permeability of the pattern to be formed is further lowered, it is preferable to have a substituent at at least a 1-position on the isoquinoline ring. The substituent is preferably an alkyl group (for example, a linear or branched alkyl group having 1 to 10 carbon atoms).

Examples of the compound β (preferably, the compound B) include monocyclic aromatic compounds such as pyridine and a pyridine derivative (preferably, pyridine, 4-acetylpyridine, 4-benzoylpyridine, or 4-dimethylaminopyridine), pyrazine and a pyrazine derivative, pyrimidine and a pyrimidine derivative, and triazine and a triazine derivative; compounds in which two rings are fused to form an aromatic ring, such as quinoline and a quinoline derivative (preferably, quinoline, 5,6,7,8-tetrahydroquinoline, 2,4,5,7-tetramethylquinoline, 2-methyl-4-methoxyquinoline, or 2,4-dimethylquinoline), isoquinoline and an isoquinoline derivative (preferably, isoquinoline, 1-phenylisoquinoline, 1-n-butylisoquinoline, 1-n-butyl-4-methylisoquinoline, or 1-methylisoquinoline), quinoxaline and a quinoxaline derivative, and quinazoline and a quinazoline derivative; and compounds in which three or more rings are fused to form an aromatic ring, such as acridine and an acridine derivative (preferably, acridine, 9-methylacridine, or 9-phenylacridine), phenanthridine and a phenanthridine derivative, phenanthroline and a phenanthroline derivative, and phenazine and a phenazine derivative.

The X derivative described above corresponds to an aspect in which X further has a substituent, and for example, the quinoline derivative corresponds to quinoline having a substituent.

Among these, from the viewpoint that the effect of the present invention is more excellent, the compound β (preferably, the compound B) preferably includes one or more selected from the group consisting of a monocyclic aromatic compound and a compound in which two rings are fused to form an aromatic ring; more preferably includes one or more compounds in which two rings are fused to form an aromatic ring; still more preferably includes one or more selected from the group consisting of isoquinoline and an isoquinoline derivative, quinoline and a quinoline derivative, quinazoline and a quinazoline derivative, quinoxaline and a quinoxaline derivative, and pyridine and a pyridine derivative; particularly preferably includes one or more selected from the group consisting of quinoline and a quinoline derivative, and isoquinoline and an isoquinoline derivative; and most preferably includes one or more selected from the group consisting of a quinoline derivative (quinoline having a substituent) and an isoquinoline derivative (isoquinoline having a substituent).

As the above-described substituent, an alkyl group, an aryl group, a halogen atom, an acyl group, an alkoxycarbonyl group, an arylcarbonyl group, a carbamoyl group, a hydroxy group, a cyano group, an amino group, or a nitro group is preferable; an alkyl group, an aryl group, a halogen atom, an acyl group, an alkoxycarbonyl group, an arylcarbonyl group, a carbamoyl group, a hydroxy group, a cyano group, or a nitro group is more preferable; an alkyl group, an aryl group, an acyl group, an alkoxycarbonyl group, an arylcarbonyl group, a carbamoyl group, a hydroxy group, a cyano group, or a nitro group is still more preferable; and an alkyl group (for example, a linear or branched alkyl group having 1 to 10 carbon atoms) is particularly preferable.

From the viewpoint of more excellent pattern forming ability and/or viewpoint that the moisture permeability of the pattern to be formed is further lowered, a molar absorption coefficient (molar absorption coefficient ε₃₆₅) of the compound β (preferably, the compound B) to light having a wavelength of 365 nm is preferably 1×10⁴ (cm·mol/L)⁻¹ or less, more preferably 1×10³ (cm·mol/L)⁻¹ or less, still more preferably less than 5×10² (cm·mol/L)⁻¹, particularly preferably 1×10² (cm·mol/L)⁻¹ or less, and most preferably less than 1×10¹ (cm·mol/L)⁻¹. The lower limit is preferably more than 0 (cm·mol/L)⁻¹.

In a case where the molar absorption coefficient ε₃₆₅ of the compound β (preferably, the compound B) is within the above-described range, it is particularly advantageous in a case where the photosensitive layer formed of the photosensitive composition is exposed through the temporary support (preferably, a PET film). That is, since the molar absorption coefficient ε₃₆₅ is moderately low, even in a case of being exposed through the temporary support, generation of bubbles due to the decarboxylation can be controlled, and deterioration of the pattern shape can be prevented.

In addition, in a case where the photosensitive composition according to the embodiment of the present invention is used for producing a permanent film, coloration of the film can be suppressed by setting the molar absorption coefficient 8 of the compound β (preferably, the compound B) within the above-described range.

As the compound having such a molar absorption coefficient ε₃₆₅, the above-described monocyclic aromatic compound or the above-described aromatic compound in which two rings are fused to form an aromatic ring is preferable, and pyridine and a pyridine derivative, quinoline and a quinoline derivative, or isoquinoline and an isoquinoline derivative is more preferable.

In addition, from the viewpoint of more excellent pattern forming ability and/or viewpoint that the moisture permeability of the pattern to be formed is further lowered, a ratio (molar absorption coefficient ε₃₆₅/molar absorption coefficient ε₃₁₃) of the molar absorption coefficient (molar absorption coefficient ε₃₆₅) of the compound 3 (preferably, the compound B) at a wavelength of 365 nm to a molar absorption coefficient (molar absorption coefficient ε₃₁₃) of the compound β (preferably, the compound B) at a wavelength of 313 nm is preferably 3 or less, more preferably 2 or less, and still more preferably less than 1. The lower limit is preferably 0.01 or more.

The molar absorption coefficient (molar absorption coefficient ε₃₆₅) of the compound β (preferably, the compound B) to light having a wavelength of 365 nm and the molar absorption coefficient (molar absorption coefficient ε₃₁₃) of the compound β (preferably, the compound B) to light having a wavelength of 313 nm are a molar absorption coefficient measured by dissolving the compound 3 (preferably, the compound B) in acetonitrile. In a case where the compound 3 (preferably, the compound B) is insoluble in acetonitrile, a solvent for dissolving the compound 3 (preferably, the compound B) may be appropriately changed.

A pKa of the compound 3 (preferably, the compound B) in a ground state is preferably 0.5 or more, and from the viewpoint of more excellent pattern forming ability and/or viewpoint that the moisture permeability of the pattern to be formed is further lowered, it is more preferably 2.0 or more. The upper limit is preferably 10.0 or less, and from the viewpoint of more excellent pattern forming ability and/or viewpoint that the moisture permeability of the pattern to be formed is further lowered, it is more preferably 9.0 or less, still more preferably 8.0 or less, and particularly preferably 7.0 or less.

The “pKa of the compound 3 (preferably, the compound B) in a ground state” is intended to be a pKa of the compound 3 (preferably, the compound B) in an unexcited state, and can be determined by acid-base titration.

The “pKa of the compound 3 (preferably, the compound B) in a ground state in a case where the compound 3 (preferably, the compound B) is a nitrogen-containing aromatic compound” is intended to be a pKa of a conjugate acid of the compound 3 (preferably, the compound B) in a ground state.

A molecular weight of the compound 3 (preferably, the compound B) is preferably less than 5,000, more preferably less than 1,000, still more preferably 65 to 300, particularly preferably 75 to 250, and most preferably 80 to 175.

In a case where the compound 3 (preferably, the compound B) is a compound exhibiting a cationic state (for example, a nitrogen-containing aromatic compound), an energy level of the highest occupied molecular orbital (HOMO) of the compound 3 (preferably, the compound B) in the cationic state is preferably −7.8 eV or less, and from the viewpoint of more excellent pattern forming ability and/or viewpoint that the moisture permeability of the pattern to be formed is further lowered, it is more preferably −8.5 eV or less. The lower limit is preferably −13.6 eV or more.

The energy level of HOMO (HOMO in the first electron excited state) of the compound β (preferably, the compound B) in the cationic state is calculated by the quantum chemical calculation program Gaussian 09 (Gaussian 09, Revision A.02, M. J. Frisch, G. W. Trucks, H. B. Schlegel, G. E. Scuseria, M. A. Robb, J. R. Cheeseman, G. Scalmani, V. Barone, B. Mennucci, G A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2009).

As a calculation method, a time-dependent density functional theory using B3LYP as a functional and 6-31+G(d,p) as a basis function is used. In addition, in order to incorporate a solvent effect, a PCM method based on a chloroform parameter set in Gaussian 09 is also used in combination. By this method, a structure optimization calculation of the first electron excited state is performed to obtain a structure with the minimum energy, and the energy of HOMO in the structure is calculated.

Hereinafter, the HOMO energy level (eV) and molecular weight of a representative example of the compound β (preferably, the compound B) in a cationic state is shown.

TABLE 1

| Compound β | | HOMO energy level in |
|---|---|---|
| (compound B) | Molecular weight | cationic state (eV) |
| Isoquinoline | 129 | −8.08 |
| Quinoline | 129 | −8.30 |
| Acridine | 179 | −7.70 |
| 2,4-Dimethylquinoline | 157 | −8.13 |
| 1-Me-isoquinoline | 143 | −7.97 |
| Pyridine | 79 | −9.63 |

The compound β (preferably, the compound B) may be used alone or in combination of two or more kinds thereof.

A content of the compound β (preferably, the compound B) is preferably 0.1% to 50% by mass with respect to the total solid content of the photosensitive composition.

In the photosensitive composition of the aspect 1, the content of the compound β (preferably, the compound B) is preferably 0.2% to 45% by mass, more preferably 1% to 40% by mass, still more preferably 2% to 35% by mass, and particularly preferably 3% to 30% by mass with respect to the total solid content of the photosensitive composition.

In the photosensitive composition of the aspect 2, the content of the compound β (preferably, the compound B) is preferably 0.5% to 20% by mass and more preferably 1.0% to 10% by mass with respect to the total solid content of the photosensitive composition.

In the photosensitive composition of the aspect 3, the content of the compound β (preferably, the compound B) is preferably 0.3% to 20% by mass, more preferably 0.5% to 10% by mass, still more preferably 1.5% to 7.5% by mass, and particularly preferably 2.5% to 6.0% by mass with respect to the total solid content of the photosensitive composition.

In the photosensitive composition, the total number of structures b0 (preferably, structures b) included in the compound 3 (preferably, the compound B) is preferably 1 mol % or more, more preferably 3 mol % or more, still more preferably 5 mol % or more, particularly preferably 10 mol % or more, and most preferably 15 mol % or more with respect to the total number of carboxy groups included in the polymer A. From the viewpoint of quality of the film to be obtained, the upper limit is preferably 200 mol % or less, more preferably 100 mol % or less, and still more preferably 80 mol % or less with respect to the total number of carboxy groups included in the polymer A.

In a case where the photosensitive composition contains a compound having a carboxy group, other than the polymer A, it is preferable that the total number of structures b0 (preferably, structures b) included in the compound 3 (preferably, the compound B) within the above-described range with respect to the total number of all carboxy groups in the photosensitive composition.

<Polymerizable Compound>

The photosensitive composition may contain a polymerizable compound.

In the photosensitive compositions of the aspects 2 and 3, the polymerizable compound is contained as an essential component.

The polymerizable compound is preferably a component different from the polymer A, and for example, is preferably a compound having a molecular weight (a weight-average molecular weight in a case of having a molecular weight distribution) of less than 5,000 and also preferably a polymerizable monomer.

The polymerizable compound is a polymerizable compound having 1 or more (for example, 1 to 15) ethylenically unsaturated groups in one molecule.

The polymerizable compound preferably includes a bi- or higher functional polymerizable compound.

The bi- or higher functional polymerizable compound means a polymerizable compound having 2 or more (for example, 2 to 15) ethylenically unsaturated groups in one molecule.

Examples of the ethylenically unsaturated group include a (meth)acryloyl group, a vinyl group, and a styryl group, and a (meth)acryloyl group is preferable.

The polymerizable compound is preferably (meth)acrylate.

The photosensitive composition preferably contains a bifunctional polymerizable compound (preferably, bifunctional (meth)acrylate) and a tri- or higher functional polymerizable compound (preferably, tri- or higher functional (meth)acrylate).

Examples of the bifunctional polymerizable compound include a known compound.

Examples thereof include tricyclodecane dimethanol di(meth)acrylate, 1,9-nonanediol di(meth)acrylate, and 1,6-hexanediol di(meth)acrylate.

Specific examples of the bifunctional polymerizable compound include tricyclodecane dimethanol diacrylate (A-DCP manufactured by Shin-Nakamura Chemical Co., Ltd.), tricyclodecane dimethanol dimethacrylate (DCP manufactured by Shin-Nakamura Chemical Co., Ltd.), 1,9-nonanediol diacrylate (A-NOD-N manufactured by Shin-Nakamura Chemical Co., Ltd.), and 1,6-hexanediol diacrylate (A-HD-N manufactured by Shin-Nakamura Chemical Co., Ltd.).

Examples of the tri- or higher functional polymerizable compound include a known compound.

Examples thereof include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

The “(tri/tetra/penta/hexa)(meth)acrylate” is a concept including tri(meth)acrylate, tetra(meth)acrylate, penta(meth)acrylate, and hexa(meth)acrylate. The “(tri/tetra)(meth)acrylate” is a concept including tri(meth)acrylate and tetra(meth)acrylate.

In addition to the above, examples of the polymerizable compound also include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd., or the like), an alkylene oxide-modified compound of a (meth)acrylate compound (KAYARAD RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., or the like), and ethoxylated glycerin triacrylate (A-GLY-9E manufactured by Shin-Nakamura Chemical Co., Ltd., or the like).

Examples of the polymerizable compound also include urethane (meth)acrylate (preferably, tri- or higher functional urethane (meth)acrylate).

The number of functional groups is preferably 3 or more, more preferably 6 or more, and still more preferably 8 or more. The upper limit is preferably 20 or less.

Examples of the tri- or higher functional urethane (meth)acrylate include 8UX-015A (manufactured by Taisei Fine Chemical Co., Ltd.); UA-32P, U-15HA, and UA-1100H (manufactured by Shin-Nakamura Chemical Co., Ltd.); AH-600 (manufactured by KYOEISHA CHEMICAL Co., LTD.); and UA-306H, UA-306T, UA-306I, UA-510H, and UX-5000 (manufactured by Nippon Kayaku Co., Ltd.).

From the viewpoint of improving developability and sweat resistance of the cured film, the polymerizable compound preferably includes a polymerizable monomer having an acid group.

Examples of the acid group include a phosphoric acid group, a sulfonic acid group, and a carboxy group, and a carboxy group is preferable.

Examples of the polymerizable compound having an acid group include a tri- or tetra-functional polymerizable compound having an acid group (compound obtained by introducing a carboxy group to pentaerythritol tri- and tetra-acrylate [PETA] skeleton (acid value=80 to 120 mgKOH/g)), and a penta- or hexa-functional polymerizable compound having an acid group (compound obtained by introducing a carboxy group to dipentaerythritol penta- and hexa-acrylate [DPHA] skeleton (acid value=25 to 70 mgKOH/g)).

The tri- or higher functional polymerizable compound having an acid group may be used in combination with the bifunctional polymerizable compound having an acid group, as necessary.

As the polymerizable compound having an acid group, one or more selected from the group consisting of a bi- or higher functional polymerizable compound having a carboxy group and a carboxylic acid anhydride thereof are preferable. As a result, the sweat resistance of the cured film is improved.

Examples of the bi- or higher functional polymerizable compound having a carboxy group include a known compound.

Examples of the bi- or higher functional polymerizable compound having a carboxy group include ARONIX (registered trademark) TO-2349 (manufactured by Toagosei Co., Ltd.), ARONIX M-520 (manufactured by Toagosei Co., Ltd.), and ARONIX M-510 (manufactured by Toagosei Co., Ltd.).

Examples of the polymerizable compound having an acid group also include polymerizable compounds having an acid group, which are described in paragraphs [0025] to of JP2004-239942A, the contents of which are incorporated in the present specification.

A weight-average molecular weight (Mw) of the polymerizable compound is preferably 200 to 3,000, more preferably 250 to 2,600, and still more preferably 250 to 2,200.

In a case where the photosensitive composition contains a polymerizable compound, among all polymerizable compounds contained in the photosensitive composition, a molecular weight of a polymerizable compound having the smallest molecular weight is preferably 200 or more and more preferably 250 or more. The upper limit is preferably 3,000 or less.

The polymerizable compound may be used alone or in combination of two or more kinds thereof.

In a case where the photosensitive composition according to the embodiment of the present invention contains a polymerizable compound, a content thereof is preferably 3% to 70% by mass, more preferably 10% to 70% by mass, and particularly preferably 20% to 55% by mass with respect to the total solid content of the photosensitive composition.

In a case where the photosensitive composition according to the embodiment of the present invention contains a polymerizable compound, a mass ratio (content of polymerizable compound/content of polymer A) of the content of the polymerizable compound to the content of the polymer A is preferably 0.2 to 2.0, more preferably 0.3 to 1.5, and still more preferably 0.4 to 1.2.

In a case where the photosensitive composition according to the embodiment of the present invention contains a bifunctional polymerizable compound and a tri- or higher functional polymerizable compound, a content of the bifunctional polymerizable compound is preferably 10% to 90% by mass, more preferably 20% to 85% by mass, and still more preferably 30% to 80% by mass with respect to all polymerizable compounds contained in the photosensitive composition. In addition, in this case, a content of the tri- or higher functional polymerizable compound is preferably 10% to 90% by mass, more preferably 15% to 80% by mass, and still more preferably 20% to 70% by mass with respect to all polymerizable compounds contained in the photosensitive composition.

In addition, in a case where the photosensitive composition according to the embodiment of the present invention contains a bi- or higher functional polymerizable compound, this photosensitive composition may further contain a monofunctional polymerizable compound.

However, in a case where the photosensitive composition according to the embodiment of the present invention contains the bi- or higher functional polymerizable compound, it is preferable that, among the polymerizable compounds which are contained in the photosensitive composition, a main component is the bi- or higher functional polymerizable compound. Specifically, in a case where the photosensitive composition according to the embodiment of the present invention contains the bi- or higher functional polymerizable compound, a content of the bi- or higher functional polymerizable compound is preferably 60% to 100% by mass, more preferably 80% to 100% by mass, and still more preferably 90% to 100% by mass with respect to all polymerizable compounds contained in the photosensitive composition.

In addition, in a case where the photosensitive composition according to the embodiment of the present invention contains a polymerizable compound having an acid group (preferably, a bi- or higher functional polymerizable compound having a carboxy group or a carboxylic acid anhydride thereof), a content of the polymerizable compound having an acid group is preferably 1% to 50% by mass, more preferably 1% to 20% by mass, and still more preferably 1% to 10% by mass with respect to the total solid content of the photosensitive composition.

<Photopolymerization Initiator>

The photosensitive composition according to the embodiment of the present invention also preferably contains a photopolymerization initiator.

In the above-described photosensitive composition of the aspect 3, the photopolymerization initiator is contained as an essential component.

Examples of the photopolymerization initiator include a photoradical polymerization initiator, a photocationic polymerization initiator, and a photoanionic polymerization initiator, and a photoradical polymerization initiator is preferable.

Examples of the photopolymerization initiator include a known photopolymerization initiator.

The photopolymerization initiator preferably includes one or more selected from the group consisting of an oxime ester compound (photopolymerization initiator having an oxime ester structure) and an aminoacetophenone compound (photopolymerization initiator having an aminoacetophenone structure), and more preferably includes both the oxime ester compound and the aminoacetophenone compound.

In a case where both the oxime ester compound and the aminoacetophenone compound are included, a content of the oxime ester compound is preferably 5% to 90% by mass, and more preferably 15% to 50% by mass with respect to the total content of the both compounds.

As the photopolymerization initiator, a photopolymerization initiator other than those described above may be used in combination.

Examples of other photopolymerization initiators include a hydroxyacetophenone compound, an acylphosphine oxide compound, and a bistriphenylimidazole compound.

Examples the photopolymerization initiator include polymerization initiators described in paragraphs [0031] to [0042] of JP2011-095716A and paragraphs [0064] to [0081] of JP2015-014783A.

Specific examples of the photopolymerization initiator include the following photopolymerization initiators.

Examples of the oxime ester compound include 1,2-octanedione, 1-[4-(phenylthio)phenyl-,2-(O-benzoyloxime)] (product name: IRGACURE OXE-01; IRGACURE series, manufactured by BASF SE), etanone,1-[9-ethyl-6-(2-methylbenzoyl)-9H-carbazol-3-yl]-,1-(0-acetyloxime) (product name: IRGACURE OXE-02, manufactured by BASF SE), [5-(2,4,6-trimethylphenyl)-11-(2-ethylhexyl)-11H-benzo[a]carbazoyl][2-(2,2,3,3-tetrafluoro propoxy)phenyl]methanone-(O-acetyloxime) (product name: IRGACURE OXE-03, manufactured by BASF SE), 1-[4-[4-(2-benzofuranylcarbonyl)phenyl]thio]phenyl]-4-methylpentanone-1-(0-acetyloxime) (product name: IRGACURE OXE-04, manufactured by BASF SE, and Lunar 6, manufactured by DKSH Management Ltd.), 1-[4-(phenylthio)phenyl]-3-cyclopentylpropan-1,2-dione-2-(O-benzoyloxime) (product name: TR-PBG-305, manufactured by Changzhou Tronly New Electronic Materials Co., Ltd.), 1,2-propanedione, 3-cyclohexyl-1-[9-ethyl-6-(2-furanylcarbonyl)-9H-carbazole-3-yl]-, 2-(O-acetyloxime) (product name: TR-PBG-326, manufactured by Changzhou Tronly New Electronic Materials Co., Ltd.), and 3-cyclohexyl-1-(6-(2-(benzoyloxyimino)hexanoyl)-9-ethyl-9H-carbazole-3-yl)-propan-1,2-dio ne-2-(O-benzoyloxime) (product name: TR-PBG-391, manufactured by Changzhou Tronly New Electronic Materials Co., Ltd.).

Examples of the aminoacetophenone compound include 2-(dimethylamino)-2-[(4-methylphenyl)methyl]-1-[4-(4-morpholinyl)phenyl]-1-butanone (product name: Omnirad 379EG; Omnirad series, manufactured by IGM Resins B.V.), 2-methyl-1-(4-methylthiophenyl)-2-morpholinopropan-1-one (product name: Omnirad 907), and APi-307 (1-(biphenyl-4-yl)-2-methyl-2-morpholinopropan-1-one, manufactured by Shenzhen UV-ChemTech Co., Ltd.).

Examples of the other photopolymerization initiators include 2-hydroxy-1-{4-[4-(2-hydroxy-2-methyl-propionyl)-benzyl]phenyl}-2-methyl-propan-1-one (product name: Omnirad 127), 2-benzyl-2-dimethylamino-1-(4-morpholinophenyl)-butanone-1 (product name: Omnirad 369), 2-hydroxy-2-methyl-1-phenyl-propan-1-one (product name: Omnirad 1173), 1-hydroxy-cyclohexyl-phenyl-ketone (product name: Omnirad 184), 2,2-dimethoxy-1,2-diphenylethane-1-one (product name: Omnirad 651), 2,4,6-trimethylbenzoyl-diphenylphosphine oxide (product name: Omnirad TPO H), and bis(2,4,6-trimethylbenzoyl) phenylphosphine oxide (product name: Omnirad 819).

The photopolymerization initiator may be used alone or in combination of two or more kinds thereof.

In a case where the photosensitive composition according to the embodiment of the present invention contains a photopolymerization initiator, a content thereof is preferably 0.1% to 15% by mass, more preferably 0.5% to 10% by mass, and still more preferably 1% to 5% by mass with respect to the total solid content of the photosensitive composition.

<Surfactant>

The photosensitive composition may contain a surfactant.

Examples of the surfactant include an anionic surfactant, a cationic surfactant, a nonionic surfactant, and an amphoteric surfactant, and a nonionic surfactant is preferable.

Examples of the nonionic surfactant include polyoxyethylene higher alkyl ethers, polyoxyethylene higher alkylphenyl ethers, polyoxyethylene glycol higher fatty acid diesters, silicone-based surfactants, and fluorine-based surfactants.

Examples of the surfactant include surfactants described in paragraphs [0120] to [0125] of WO2018/179640A, paragraph [0017] of JP4502784B, and paragraphs [0060] to [0071] of JP2009-237362A.

Examples of the fluorine-based surfactant include: MEGAFACE F-171, F-172, F-173, F-176, F-177, F-141, F-142, F-143, F-144, F-437, F-475, F-477, F-479, F-482, F-551-A, F-551, F-552, F-554, F-555-A, F-556, F-557, F-558, F-559, F-560, F-561, F-565, F-563, F-568, F-575, F-780, EXP, MFS-330, MFS-578, MFS-579, MFS-586, MFS-587, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by AGC Inc.); and POLYFOX PF636, PF656, PF6320, PF6520, and PF7002 (all of which are manufactured by OMNOVA Solutions Inc.); FTERGENT 710FL, 710FM, 610FM, 601AD, 601ADH2, 602A, 215M, 245F, 251, 212M, 250, 209F, 222F, 208G 710LA, 710FS, 730LM, 650AC, 681, and 683 (all of which are manufactured by NEOS COMPANY LIMITED).

In addition, as the fluorine-based surfactant, an acrylic compound, which has a molecular structure having a functional group including a fluorine atom and in which, by applying heat to the molecular structure, the functional group including a fluorine atom is broken to volatilize a fluorine atom, is also preferable. Examples of such a fluorine-based surfactant include MEGAFACE DS series manufactured by DIC Corporation (The Chemical Daily (Feb. 22, 2016) and Nikkei Business Daily (Feb. 23, 2016)), and MEGAFACE DS-21 is preferable.

As the fluorine-based surfactant, a polymer of a fluorine atom-containing vinyl ether compound having a fluorinated alkyl group or a fluorinated alkylene ether group, and a hydrophilic vinyl ether compound is also preferably used. In addition, the fluorine-based surfactant may be a block polymer.

As the fluorine-based surfactant, a fluorine-containing polymer including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) is also preferable.

In addition, the fluorine-based surfactant may be a fluorine-containing polymer having an ethylenically unsaturated bond-containing group in a side chain, and examples thereof include MEGAFACE RS-101, RS-102, RS-718K, and RS-72-K (all of which are manufactured by DIC Corporation).

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters; PLURONIC L10, L31, L61, L62, 10R5, 17R2, and 25R² (all of which are manufactured by BASF SE); TETRONIC 304, 701, 704, 901, 904, and 150R1 (all of which are manufactured by BASF SE); SOLSPERSE 20000 (manufactured by Lubrizol Corporation); NCW-101, NCW-1001, and NCW-1002 (all of which are manufactured by FUJIFILM Wako Pure Chemical Corporation); PIONIN D-6112, D-6112-W, and D-6315 (all of which are manufactured by Takemoto Oil&Fat Co., Ltd.); and OLFINE E1010 and SURFYNOL 104, 400, and 440 (all of which are manufactured by Nissin Chemical Co., Ltd.).

Examples of the silicone-based surfactant include a linear polymer consisting of a siloxane bond and a modified siloxane polymer with an organic group introduced in the side chain and/or the terminal.

Specific examples of the surfactant include DOWSIL 8032 ADDITIVE, TORAY SILICONE DC3PA, TORAY SILICONE SH7PA, TORAY SILICONE DCllPA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.); X-22-4952, X-22-4272, X-22-6266, KF-351A, K354L, KF-355A, KF-945, KF-640, KF-642, KF-643, X-22-6191, X-22-4515, KF-6004, KP-341, KF-6001, and KF-6002 (all of which are manufactured by Shin-Etsu Silicone Co., Ltd.); F-4440, TSF-4300, TSF-4445, TSF-4460, and TSF-4452 (all of which are manufactured by Momentive Performance Materials Co., Ltd.); and BYK307, BYK323, and BYK330 (all of which are manufactured by BYK Chemie).

The surfactant may be used alone or in combination of two or more kinds thereof.

In a case where the photosensitive composition contains a surfactant, a content of the surfactant is preferably 0.0001% to 10% by mass, more preferably 0.001% to 5% by mass, and still more preferably 0.005% to 3% by mass with respect to the total solid content of the photosensitive composition.

<Solvent>

From the viewpoint of forming the photosensitive layer by coating, the photosensitive composition may contain a solvent.

Examples of the solvent include a known solvent, and an organic solvent is preferable.

Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, 2-propanol, and a mixed solvent thereof.

As the solvent, a mixed solvent of methyl ethyl ketone and propylene glycol monomethyl ether acetate, a mixed solvent of diethylene glycol ethyl methyl ether and propylene glycol monomethyl ether acetate, or a mixed solvent of methyl ethyl ketone, propylene glycol monomethyl ether, and propylene glycol monomethyl ether acetate is preferable.

In a case where the photosensitive composition according to the embodiment of the present invention contains a solvent, the solid content of the photosensitive composition is preferably 5% to 80% by mass, more preferably 8% to 40% by mass, and still more preferably 10% to 30% by mass. That is, in a case where the photosensitive composition according to the embodiment of the present invention contains a solvent, a content of the solvent is preferably 20% to 95% by mass, more preferably 60% to 95% by mass, and still more preferably 70% to 95% by mass with respect to the total mass of the photosensitive composition.

In a case where the photosensitive composition according to the embodiment of the present invention contains a solvent, from the viewpoint of coating properties, a viscosity (25° C.) of the photosensitive composition is preferably 1 to 50 mPa-s, more preferably 2 to 40 mPa-s, and still more preferably 3 to 30 mPa-s.

Examples of a method for measuring the viscosity include a VISCOMETER TV-22 (manufactured by TOKI SANGYO CO., LTD.).

In a case where the photosensitive composition according to the embodiment of the present invention contains a solvent, from the viewpoint of coating properties, a surface tension (25° C.) of the photosensitive composition is preferably 5 to 100 mN/m, more preferably 10 to 80 mN/m, and still more preferably 15 to 40 mN/m.

The surface tension is measured using, for example, Automatic Surface Tensiometer CBVP-Z (manufactured by Kyowa Interface Science Co., Ltd.).

Examples of the solvent include Solvent described in paragraphs [0054] and [0055] of US2005/282073A, the contents of which are incorporated in the present specification. In addition, as the solvent, an organic solvent (high-boiling-point solvent) having a boiling point of 180° C. to 250° C. may be used as necessary.

It is preferable that the above-described photosensitive layer does not substantially contain the solvent.

The “does not substantially contain the solvent” means that the content of the solvent is less than 1% by mass, preferably 0% to 0.5% by mass and more preferably 0% to 0.001% by mass with respect to the total mass of the photosensitive layer.

<Other Components>

The photosensitive composition according to the embodiment of the present invention may contain a component other than the above-described components.

Examples of other components include known additives such as a metal oxidation inhibitor which can be contained in the layer of high refractive index described above, metal oxide particles, an antioxidant, a dispersing agent, an acid proliferation agent, a development promoter, a conductive fiber, a colorant, a thermal radical polymerization initiator, a thermal acid generator, an ultraviolet absorber, a thickener, a crosslinking agent, and an organic or inorganic anti-precipitation agent.

Examples of a suitable aspect of other components include paragraphs [0165] to [0184] of JP2014-085643A, the contents of which are incorporated in the present specification.

In a case where the photosensitive composition contains a metal oxidation inhibitor, a content of the metal oxidation inhibitor is preferably 0.01% to 10% by mass, more preferably 0.01% to 5% by mass, and still more preferably 0.05% to 1% by mass with respect to the total solid content of the photosensitive composition.

The photosensitive composition may contain impurities.

Examples of the impurities include sodium, potassium, magnesium, calcium, iron, manganese, copper, aluminum, titanium, chromium, cobalt, nickel, zinc, tin, halogen, and ions of these. Among these, halide ion, sodium ion, and potassium ion are easily mixed as impurities, so that the following content is preferable.

A content of the impurities in the photosensitive composition is preferably 80 ppm by mass or less, more preferably 10 ppm by mass or less, and still more preferably 2 ppm by mass or less with respect to the total mass of the photosensitive composition. The lower limit is preferably 1 ppb by mass or more, and more preferably 0.1 ppm by mass or more with respect to the total mass of the photosensitive composition.

Examples of a method for adjusting the content of the impurities include a method of selecting a raw material having a low content of impurities as a raw material for the photosensitive composition, a method of preventing the impurities from being mixed in a case of forming the photosensitive composition, and a method of washing and removing the impurities.

As a measuring method of the content of the impurities, a known method such as ICP emission spectroscopy, atomic absorption spectroscopy, and ion chromatography can be used for quantification.

In the photosensitive composition, it is preferable that the content of compounds such as benzene, formaldehyde, trichlorethylene, 1,3-butadiene, carbon tetrachloride, chloroform, N,N-dimethylformamide, N,N-dimethylacetamide, and hexane is low.

Specifically, each content of the above-described compounds is preferably 100 ppm by mass or less, more preferably 20 ppm by mass or less, and still more preferably 4 ppm by mass or less with respect to the total mass of the photosensitive composition. The lower limit is preferably 10 ppb by mass or more, and more preferably 100 ppb by mass or more with respect to the total mass of the photosensitive composition.

Examples of a method for adjusting the content of the above-described compounds include the method for adjusting the content of the impurities. In addition, as a measuring method of the content of the above-described compounds, for example, a known measuring method can be used for quantification.

From the viewpoint of improving patterning properties, a content of water in the photosensitive composition is preferably 0.01% by mass or more and less than 1.0% by mass, and more preferably 0.05% to 0.5% by mass with respect to the total mass of the photosensitive composition.

[Pattern Forming Method]

As long as it is a pattern forming method using the photosensitive composition according to the embodiment of the present invention, the pattern forming method related to the present invention (hereinafter, also referred to as “pattern forming method according to the embodiment of the present invention”) preferably includes a step of forming a photosensitive layer on a base material using the photosensitive composition according to the embodiment of the present invention, a step of exposing the photosensitive layer in a patterned manner, and a step of developing the exposed photosensitive layer (alkali development or organic solvent development). In a case where the above-described development is an organic solvent development, it is preferable to include a step of further exposing the obtained pattern.

In forming the photosensitive layer on the base material using the photosensitive composition according to the embodiment of the present invention, a method in which the above-described transfer film is produced using the photosensitive composition, and such a transfer film is used to form the photosensitive layer on the base material may be used. Specifically, examples of such a method include a method in which a surface of the photosensitive layer in the above-described transfer film on an opposite side of the temporary support side is brought into contact with the base material to bond the transfer film and the base material, and then the photosensitive layer in the transfer film is used as the photosensitive layer on the base material.

Examples of specific embodiments of the pattern forming method according to the present invention include the pattern forming methods of the embodiment 1 and the embodiment 2.

Hereinafter, each step of the pattern forming methods of the embodiment 1 and the embodiment 2 will be described in detail.

### Pattern Forming Method of Embodiment 1

A pattern forming method of an embodiment 1 includes steps X1 to X3.

The following step X2 corresponds to a step of reducing the content of the carboxy group derived from the polymer A in the photosensitive layer by the exposure. However, in a case where a developer in the step X3 is an organic solvent-based developer, a step X4 is further included after the step X3.
Step X1: step of forming a photosensitive layer on a base material using the photosensitive composition according to the embodiment of the present invention
Step X2: step of exposing the photosensitive layer in a patterned manner
Step X3: step of developing the photosensitive layer exposed in a patterned manner with a developer
Step X4: step of further exposing the pattern formed by the development after the developing step of the step X3

In a case where an alkali developer is used as the developer in the step X3, the above-described photosensitive composition layer is preferably the photosensitive composition of the aspect 1 or the aspect 2. In a case where an organic solvent-based developer is used as the developer in the step X3, the above-described photosensitive composition layer is preferably the photosensitive composition of the aspect 1.

In addition, the pattern forming method of the embodiment 1 is preferably adopted to a transfer film including a photosensitive layer X formed of the photosensitive composition of the aspect 1 or the aspect 2 described above.

(Step X1)

The pattern forming method of the embodiment 1 includes a step of forming a photosensitive layer on a base material using the photosensitive composition according to the embodiment of the present invention.

Base Material

Examples of the base material include a glass substrate, a silicon substrate, a resin substrate, and a substrate having a conductive layer.

Examples of the substrate included in the substrate having a conductive layer include a glass substrate, a silicon substrate, and a resin substrate.

The above-described base material is preferably transparent.

A refractive index of the above-described base material is preferably 1.50 to 1.52.

The above-described base material may be composed of a translucent substrate such as a glass substrate, and for example, tempered glass typified by Gorilla glass of Corning can also be used. In addition, as the material included in the above-described base material, materials used in JP2010-086684A, JP2010-152809A, and JP2010-257492A are also preferable.

In a case where the above-described base material includes a resin substrate, as the resin substrate, it is more preferable to use a resin film having a small optical distortion and/or a high transparency. Specific examples of the material include polyethylene terephthalate (PET), polyethylene naphthalate, polycarbonate, triacetyl cellulose, and a cycloolefin polymer.

As the substrate included in the substrate having a conductive layer, from the viewpoint of manufacturing by roll-to-roll method, a resin substrate is preferable and a resin film is more preferable.

Examples of the conductive layer include any conductive layer used for a known circuit wiring or touch panel wiring.

As the conductive layer, from the viewpoint of conductivity and fine line formability, one or more layers selected from the group consisting of a metal layer, a conductive metal oxide layer, a graphene layer, a carbon nanotube layer, and a conductive polymer layer are preferable, a metal layer is more preferable, and a copper layer or a silver layer is still more preferable.

In addition, the conductive layer in the substrate having a conductive layer may be one layer or two or more layers.

In a case where the substrate having a conductive layer includes two or more conductive layers, it is preferable that each conductive layer is a conductive layer formed of different materials.

Examples of a material of the conductive layer include simple substances of metal and conductive metal oxides.

Examples of the simple substance of metal include Al, Zn, Cu, Fe, Ni, Cr, Mo, Ag, and Au.

Examples of the conductive metal oxide include indium tin oxide (ITO), indium zinc oxide (IZO), and SiO₂. The “conductive” means that a volume resistivity is less than 1×10⁶ Ω·cm, and the volume resistivity is preferably less than 1×10⁴ Ω·cm.

In a case where the number of conductive layers in the substrate having a conductive layer is 2 or more, it is preferable that at least one conductive layer among the conductive layers includes the conductive metal oxide.

The conductive layer is preferably an electrode pattern corresponding to a sensor in a visual recognition portion used for a capacitive touch panel or a wiring line for a peripheral wiring portion.

In addition, the conductive layer is preferably a transparent layer.

Procedure of Step X1

The step X1 is not particularly limited as long as the photosensitive layer can be formed on the base material by using the photosensitive composition according to the embodiment of the present invention.

For example, a photosensitive composition containing a solvent may be applied to the base material to form a coating film, and the coating film may be dried to form the photosensitive layer on the base material. Examples of such a method of forming the photosensitive layer on the base material include the same method as the method for forming the photosensitive layer described in the transfer film above.

In addition, it is also preferable that the photosensitive composition used for forming the photosensitive layer on the base material in the step X1 is the photosensitive composition contained in the above-described transfer film (photosensitive layer included in the transfer film). That is, it is also preferable that the photosensitive layer formed in the step X1 is a layer formed by using the above-described transfer film.

In a case where the photosensitive layer is formed on the base material by using the transfer film, the step X1 is preferably a step of bringing a surface of the photosensitive layer in the transfer film on an opposite side of the temporary support side into contact with the base material to bond the transfer film and the base material. Such a step is also particularly referred to as a step X1b.

The step X1b is preferably a bonding step of pressurization by a roll or the like and heating. A known laminator such as a laminator, a vacuum laminator, and an auto-cut laminator can be used for the bonding.

The step X1b is preferably performed by a roll-to-roll method, and therefore, the base material to which the transfer film is bonded is preferably a resin film or a resin film having a conductive layer.

Hereinafter, the roll-to-roll method will be described.

The roll-to-roll method refers to a method in which, as the base material, a base material which can be wound up and unwound is used, a step (also referred to as an “unwinding step”) of unwinding the base material before any of the steps included in the pattern forming method according to the embodiment of the present invention, a step (also referred to as a “winding step”) of winding the base material is included after any of the steps, and at least one of the steps (preferably, all steps or all steps other than the heating step) is performed while transporting the base material.

As an unwinding method in the unwinding step and a winding method in the winding step, a known method may be used in the manufacturing method to which the roll-to-roll method is adopted.

(Step X2)

The pattern forming method of the embodiment 1 includes a step (step X2) of exposing the photosensitive layer in a patterned manner after the above-described step X1. The step X2 corresponds to a step of reducing the content of the carboxy group derived from the polymer A in the photosensitive layer by the exposure. More specifically, it is preferable that, by using light having a wavelength which excites the structure b0 (preferably, the structure b) in the photosensitive layer, the photosensitive layer is exposed in a patterned manner.

Detailed arrangement and specific size of the pattern in the exposing step are not particularly limited.

For example, in a case where the pattern forming method of the embodiment 1 is adopted to the manufacturing of a circuit wiring, from the viewpoint of improving display quality of a display device (for example, a touch panel) including an input device having the circuit wiring manufactured by the pattern forming method of the embodiment 1, and viewpoint of reducing an area occupied by a lead-out wiring as much as possible, at least a part of the pattern (in particular, a portion corresponding to a portion of the electrode pattern of the touch panel and the lead-out wiring) is preferably a thin line having a width of 100 μm or less, and more preferably a thin line having a width of 70 μm or less.

As a light source used for the exposure, any light source which radiates light in a wavelength range capable of reducing the content of the carboxy group derived from the polymer A in the photosensitive layer (light having a wavelength which excites the structure b0 (preferably, the structure b) in the photosensitive layer; for example, light in a wavelength range of 254 nm, 313 nm, 365 nm, 405 nm, 436 nm, and the like) can be appropriately selected. Specific examples thereof include an ultra-high pressure mercury lamp, a high pressure mercury lamp, a metal halide lamp, and a light emitting diode (LED).

An exposure amount is preferably 10 to 10000 mJ/cm² and more preferably 50 to 3000 mJ/cm².

In a case where the step X1 is the step X1b, in the step X2, the temporary support may be peeled off from the photosensitive layer and then the pattern exposure may be performed, or before peeling off the temporary support, the pattern exposure may be performed through the temporary support and then the temporary support may be peeled off. In order to prevent mask contamination due to contact between the photosensitive layer and the mask and to avoid an influence of foreign substance adhering to the mask on the exposure, it is preferable to perform the pattern exposure without peeling off the temporary support. The pattern exposure may be an exposure through a mask or a direct exposure using a laser or the like.

(Step X3)

The pattern forming method of the embodiment 1 includes a step (step X3) of, after the above-described step X2, developing the photosensitive layer exposed in a patterned manner with a developer (alkali developer or organic solvent-based developer).

By reducing the content of the carboxy group in the photosensitive layer of the exposed portion, a difference in solubility (dissolution contrast) in the developer may occur between the exposed portion and the non-exposed portion of the photosensitive layer which has undergone the step X2. By forming the dissolution contrast in the photosensitive layer, it is possible to form a pattern in the step X3. In a case where the developer in the above-described step X3 is an alkali developer, the non-exposed portion is removed and a negative pattern is formed by performing the above-described step X3. On the other hand, in a case where the developer in the above-described step X3 is an organic solvent-based developer, the exposed portion is removed and a positive pattern is formed by performing the above-described step X3. For the obtained positive pattern, it is necessary to perform a treatment for reducing the content of the carboxy group derived from the polymer A by the step X4 described later.

Alkali Developer

The alkali developer is not particularly limited as long as, for example, it can remove the non-exposed portion of the photosensitive layer.

Examples of the alkali developer include a known developer such as the developer described in JP1993-072724A (JP-H5-072724A).

As the alkali developer, for example, an alkali aqueous solution-based developer including a compound having a pKa of 7 to 13 at a concentration of 0.05 to 5 mol/L is preferable.

In addition, the alkali developer may further include a water-soluble organic solvent, a surfactant, and the like. As the alkali developer, developers described in paragraph [0194] of WO2015/093271A are also preferable.

Organic Solvent-Based Developer

The organic solvent-based developer is not particularly limited as long as, for example, it can remove the exposed portion of the photosensitive layer.

Examples of the organic solvent-based developer include developers including an organic solvent such as a ketone-based solvent, an ester-based solvent, an alcohol-based solvent, an amide-based solvent, an ether-based solvent, and a hydrocarbon-based solvent.

In the organic solvent-based developer, a plurality of organic solvents may be mixed, or may be mixed with an organic solvent other than the above or water and used. A moisture content of the organic solvent-based developer as a whole is preferably less than 10% by mass, and the organic solvent-based developer is more preferably substantially free of the moisture (preferably, less than 1% by mass).

The content of the organic solvent (in a case of mixing a plurality of organic solvents, a total thereof) is preferably 50% by mass or more, more preferably 60% by mass or more, still more preferably 85% by mass or more, particularly preferably 90% by mass or more, and most preferably 95% by mass or more with respect to the total mass of the organic solvent-based developer. The upper limit is preferably 100% by mass or less.

Examples of the developing method include puddle development, shower development, spin development, and dip development. The shower development is a development method in which unnecessary portions can be removed by spraying the developer on the photosensitive layer after the exposure with a shower. In addition, after the development, it is also preferable to spray a washing agent and the like with a shower and rub with a brush and the like to remove the developing residue. A liquid temperature of the developer is preferably 20° C. to 40° C.

The pattern forming method of the embodiment 1 may further include a post-baking step of heat-treating a pattern including the photosensitive layer obtained by development.

The post-baking is preferably performed in an environment of 8.1 to 121.6 kPa, and more preferably performed in an environment of 50.66 kPa or more. On the other hand, it is more preferably performed in an environment of 111.46 kPa or less, and still more preferably performed in an environment of 101.3 kPa or less.

A temperature of the post-baking is preferably 80° C. to 250° C., more preferably 110° C. to 170° C., and still more preferably 130° C. to 150° C.

A time of the post-baking is preferably 1 to 60 minutes, more preferably 2 to 50 minutes, and still more preferably 5 to 40 minutes.

The post-baking may be performed in an air environment or a nitrogen replacement environment.

(Step X4)

In a case where the developer in the above-described step X3 is an organic solvent-based developer, the step X4 is performed on the obtained positive pattern. The step X4 corresponds to a step of exposing the positive pattern obtained in the step X3 to reduce the content of the carboxy group derived from the polymer A. More specifically, it is preferable that, by using light having a wavelength which excites the structure b0 (preferably, the structure b) in the photosensitive layer, the photosensitive layer is exposed in a patterned manner.

A light source and exposure amount used for the exposure are the same as the light source and exposure amount described in the step X1, and suitable aspects thereof are also the same.

### Pattern Forming Method of Embodiment 2

A pattern forming method of an embodiment 2 includes a step Y1, a step Y2P, and a step Y3 in this order, and further includes a step Y2Q (step of further exposing the photosensitive layer exposed in the step Y2P) between the step Y2P and the step Y3 or after the step Y3.

Step Y1: step of forming a photosensitive layer on a base material using the photosensitive composition according to the embodiment of the present invention
Step Y2P: step of exposing the photosensitive layer
Step Y2Q: step of further exposing the exposed photosensitive layer
Step Y3: step of developing the photosensitive layer with a developer

The pattern forming method of the embodiment 2 is preferably adopted to a case where the photosensitive layer further includes a photopolymerization initiator and a polymerizable compound. Therefore, the pattern forming method of the embodiment 2 is preferably adopted to the photosensitive composition of the aspect 3 described above.

Hereinafter, the pattern forming method of the embodiment 2 will be described, but the step Y1 and the step Y3 are the same as the step X1 and the step X3, respectively, so that the description thereof will be omitted.

It is sufficient that the step Y3 is performed at least after the step Y2P, and the step Y3 may be performed between the step Y2P and the step Y2Q.

The pattern forming method of the embodiment 2 may further include, after the step Y3, a post-baking step of heat-treating a pattern including the photosensitive layer obtained by development. The post-baking step can be performed by the same method as the post-baking step which may be included in the above-described pattern forming method of the embodiment 1. In a case where the step Y3 is performed between the step Y2P and the step Y2Q, the post-baking step may be performed before the step Y2Q or after the step Y2Q as long as it is performed after the step Y3.

(Step Y2P and Step Y2Q)

The pattern forming method of the embodiment 2 includes a step (step Y2P) of exposing the photosensitive layer through the step Y1 and a step (step Y2Q) of further exposing the exposed photosensitive layer.

One of the exposure treatments (the step Y2P and the step Y2Q) is an exposure for mainly reducing the content of the carboxy group of the polymer A by the exposure, and the other one of the exposure treatments (the step Y2P and the step Y2Q) is an exposure for mainly causing a polymerization reaction of the polymerizable compound based on the photopolymerization initiator. In addition, the exposure treatments (the step Y2P and the step Y2Q) may be either the entire exposure or the pattern exposure, but any one of the exposure treatments is the pattern exposure.

For example, in a case where the step Y2P is a pattern exposure for reducing the content of the carboxy group of the polymer A by the exposure, the developer used in the step Y3 may be an alkali developer or an organic solvent-based developer. However, in a case of developing with an organic solvent-based developer, the step Y2Q is usually performed after the step Y3, and in the developed photosensitive layer (pattern), the polymerization reaction of the polymerizable compound based on the photopolymerization initiator occurs, and the content of the carboxy group derived from the polymer A is reduced.

In addition, for example, in a case where the step Y2P is a pattern exposure for causing a polymerization reaction of the polymerizable compound based on the photopolymerization initiator, the developer used in the step Y3 is usually an alkali developer. In this case, the step Y2Q may be performed before or after the step Y3, and the step Y2Q in a case of being performed before the step Y3 is usually a pattern exposure.

In the step Y2P and the step Y2Q, as a light source used for the exposure, any light source which radiates light in a wavelength range capable of reducing the content of the carboxy group of the polymer A in the photosensitive layer (light having a wavelength which excites the structure b0 (preferably, the structure b) in the photosensitive layer; for example, light in a wavelength range of 254 nm, 313 nm, 365 nm, 405 nm, and the like) or light in a wavelength range capable of causing a reaction of the polymerizable compound based on the photopolymerization initiator in the photosensitive layer (light having a wavelength which exposes the photopolymerization initiator; for example, light in a wavelength range of 254 nm, 313 nm, 365 nm, 405 nm, and the like) can be appropriately selected. Specific examples thereof include an ultra-high pressure mercury lamp, a high pressure mercury lamp, a metal halide lamp, and an LED.

In the exposure for reducing the content of the carboxy group of the polymer A in the photosensitive layer, an exposure amount is preferably 10 to 10000 mJ/cm², and more preferably 50 to 3000 mJ/cm².

In the exposure for causing a reaction of the polymerizable compound based on the photopolymerization initiator in the photosensitive layer, an exposure amount is preferably 5 to 200 mJ/cm², and more preferably 10 to 150 mJ/cm².

In a case where the step Y1 is performed in the same method as shown as the step X1b, in the step Y2P and/or the step Y2Q, the temporary support may be peeled off from the photosensitive layer and then the pattern exposure may be performed, or before peeling off the temporary support, the pattern exposure may be performed through the temporary support and then the temporary support may be peeled off. In order to prevent mask contamination due to contact between the photosensitive layer and the mask and to avoid an influence of foreign substance adhering to the mask on the exposure, it is preferable to perform the pattern exposure without peeling off the temporary support. The pattern exposure may be an exposure through a mask or a direct exposure using a laser or the like.

Detailed arrangement and specific size of the pattern in the exposing step are not particularly limited.

For example, in a case where the pattern forming method of the embodiment 2 is adopted to the manufacturing of a circuit wiring, from the viewpoint of improving display quality of a display device (for example, a touch panel) including an input device having the circuit wiring manufactured by the pattern forming method of the embodiment 2, and viewpoint of reducing an area occupied by a lead-out wiring as much as possible, at least a part of the pattern (in particular, a portion corresponding to a portion of the electrode pattern of the touch panel and the lead-out wiring) is preferably a thin line having a width of 100 μm or less, and more preferably a thin line having a width of 70 μm or less.

(Suitable Aspect)

Among these, as the pattern forming method of the embodiment 2, it is preferable that the step Y2P is a step Y2A, the step Y2Q is a step Y2B, a step Y1, a step Y2A, a step Y3, and a step Y2B are included in this order. One of the step Y2A and the step Y2B is an exposing step for reducing the content of the carboxy group of the polymer A by the exposure, and the other is an exposing step for causing a reaction between the photopolymerization initiator and the polymerizable compound.

Step Y1: step of forming a photosensitive layer on a base material using the photosensitive composition according to the embodiment of the present invention (preferably, a step of bringing a surface of the photosensitive layer in the transfer film on an opposite side of the temporary support side into contact with the base material to bond the transfer film and the base material)
Step Y2A: step of exposing the photosensitive layer in a patterned manner
Step Y3: step of developing the photosensitive layer with an alkali developer to form a patterned photosensitive layer
Step Y2B: step of exposing the patterned photosensitive layer

The above-described step Y2A is preferably an exposing step for causing a reaction between the photopolymerization initiator and the polymerizable compound, and the above-described step Y2B is preferably an exposing step for reducing the content of the carboxy group derived from the polymer A by the exposure.

### Optional Step which May be Included in Pattern Forming Methods of Embodiment 1 and Embodiment 2

The pattern forming methods of the embodiment 1 and the embodiment 2 may include optional steps (other steps) in addition to those described above.

Examples thereof include the following steps, but the other steps are not limited to these steps.

(Cover Film Peeling Step)

In the above-described pattern forming method, in a case where the photosensitive layer is formed on the base material using the transfer film and the transfer film has a cover film, it is preferable to include a step (hereinafter, also referred to as a “cover film peeling step”) of peeling off the cover film of the transfer film. As a method of peeling off the cover film, and a known method can be adopted.

(Step of Reducing Visible Light Reflectivity)

In a case where the substrate is the substrate having a conductive layer, the above-described pattern forming method may further include a step of performing a treatment of reducing a visible light reflectivity of the conductive layer. In a case where the above-described substrate is a substrate having a plurality of conductive layers, the treatment of reducing the visible light reflectivity may be performed on some conductive layers or all conductive layers.

Examples of the treatment of reducing the visible light reflectivity include an oxidation treatment. For example, by oxidizing copper to copper oxide, the visible light reflectivity of the conductive layer can be reduced due to blackening.

Examples of a suitable aspect of the treatment of reducing the visible light reflectivity include the descriptions in paragraphs [0017] to [0025] of JP2014-150118A, and paragraphs [0041], [0042], [0048], and [0058] of JP2013-206315A, the contents of which are incorporated in the present specification.

(Etching Step)

In a case where the substrate is the substrate having a conductive layer, the above-described pattern forming method preferably includes a step (etching step) of etching, using the pattern formed by the step X3 (or the step X4) and the step Y3 as an etching resist film, the conductive layer in a region where the etching resist film is not disposed.

Examples of a method of the etching treatment, include a method by wet etching, which is described in paragraphs [0048] to [0054] of JP2010-152155A, and a method by dry etching such as a known plasma etching.

Examples of the method of the etching treatment include a wet etching method by immersing in a known etchant. As the etchant used for the wet etching, an acidic type or alkaline type etchant may be appropriately selected according to the etching target.

Examples of the acidic type etchant include aqueous solutions of acidic component alone, such as hydrochloric acid, sulfuric acid, hydrofluoric acid, and phosphoric acid, and mixed aqueous solutions of an acidic component and a salt such as ferric chloride, ammonium fluoride, and potassium permanganate. As the acidic component, a component in which a plurality of acidic components is combined may be used.

Examples of the alkaline type etchant include aqueous solutions of alkaline component alone, such as sodium hydroxide, potassium hydroxide, ammonia, organic amine, and a salt of organic amine such as tetramethylammonium hydroxide, and mixed aqueous solutions of an alkaline component and a salt such as potassium permanganate. As the alkaline component, a component in which a plurality of alkaline components is combined may be used.

A temperature of the etchant is preferably 45° C. or lower. The lower limit is preferably 0° C. or higher.

In a manufacturing method of a circuit wiring according to the present invention, the pattern formed by the step X3 (or the step X4) and the step Y3 used as the etching resist film preferably exhibits particularly excellent resistance to the acidic and alkaline etchant in a temperature range of 45° C. or lower. With the above-described configuration, the etching resist film is prevented from peeling off during the etching step, and a portion where the etching resist film does not exist is selectively etched.

After the etching step, in order to prevent contamination of the process line, a washing step of washing the etched substrate and a drying step of drying the washed substrate may be performed as necessary.

The film used as the etching resist film may be removed, or may not be removed and be used as a protective film (permanent film) for a conductive layer of a circuit wiring.

### Other Embodiments

As the above-described pattern forming method, it is also preferable to use a substrate having a plurality of conductive layers on both surfaces and sequentially or simultaneously form a pattern on the conductive layers formed on both surfaces.

With such a configuration, it is possible to form a first conductive pattern is formed on one surface of the substrate and form a second conductive pattern on the other surface. It is also preferable to form from both surfaces of the base material by the roll-to-roll.

<Pattern>

The pattern formed by the above-described pattern forming methods of the embodiment 1 and the embodiment 2 has reduced content of the carboxy group, so that polarity, relative permittivity, and/or moisture permeability is lowered.

The content of the carboxy group in the above-described pattern is preferably reduced by 5 mol % or more, more preferably reduced by 10 mol % or more, still more preferably reduced by 20 mol % or more, even more preferably reduced by 31 mol % or more, particularly preferably reduced by 40 mol % or more, more particularly preferably reduced by 51 mol % or more, and most preferably reduced by 71 mol % or more with respect to the content of the carboxy group in the photosensitive layer formed in the step X1 or the step Y1. The upper limit is preferably 100 mol % or less.

The moisture permeability of the above-described pattern is preferably reduced by 5% or more, more preferably reduced by 10% or more, and still more preferably reduced by 20% or more with respect to the moisture permeability of the photosensitive layer formed in the step X1 or the step Y1. The upper limit is preferably 100% or less.

The relative permittivity of the above-described pattern is preferably reduced by 5% or more, more preferably reduced by 10% or more, and still more preferably reduced by 15% or more with respect to the relative permittivity of the photosensitive layer formed in the step X1 or the step Y1. The upper limit value is preferably 100% or less.

An average thickness of the pattern formed by the above-described pattern forming method is preferably 0.5 to 20 μm, more preferably 0.8 to 15 μm, and still more preferably 1.0 to 10 μm.

The pattern formed by the above-described pattern forming method is preferably achromatic. Specifically, in CIE1976 (L*, a*, b*) color space, the total reflection (incidence angle: 8°, light source: D-65 (visual field: 2°)) preferably has a pattern L* value of 10 to 90, preferably has a pattern a* value of −1.0 to 1.0, and preferably has a pattern b* value of −1.0 to 1.0.

Each value in the CIE1976 (L*, a*, b*) color space can be measured by a known method.

As use of the pattern formed by the above-described pattern forming method, the pattern can be used as various protective films or insulating films.

Specific examples thereof include the use as a protective film (permanent film) which protects a conductive pattern, the use as an interlayer insulating film between conductive patterns, and the use as an etching resist film in the manufacturing of the circuit wiring. The above-described pattern is preferably used as a protective film (permanent film) which protects the conductive pattern or as an interlayer insulating film between the conductive patterns. In addition, after using the pattern as an etching resist film, it may be used as it as a protective film (permanent film).

The above-described pattern can be used as a protective film (permanent film) which protects a conductive pattern such as an electrode pattern corresponding to a sensor in a visual recognition portion and a wiring line for a peripheral wiring portion and a lead-out wiring portion is provided inside the touch panel, or as an interlayer insulating film between conductive patterns.

[Manufacturing Method of Circuit Wiring]

The present invention also relates to a manufacturing method of a circuit wiring.

As long as it is a manufacturing method of a circuit wiring using the above-described photosensitive composition, the manufacturing method of a circuit wiring related to the present invention (hereinafter, also referred to as “manufacturing method of a circuit wiring according to the embodiment of the present invention) preferably includes, in the following order, a step (photosensitive layer forming step) of forming a photosensitive layer on a conductive layer in a substrate having a conductive layer using a photosensitive composition (preferably, the photosensitive composition of the aspect 3), a step (first exposing step) of exposing the photosensitive layer in a patterned manner, a step (alkali developing step) of developing the exposed photosensitive layer with an alkali developer to form a patterned photosensitive layer, a step (second exposing step) of exposing the patterned photosensitive layer to form an etching resist film, and a step (etching step) of etching the conductive layer in a region on which the etching resist film is not disposed.

The above-described photosensitive layer forming step is also preferably a step (bonding step) of bringing a surface of the photosensitive layer in the above-described transfer film on an opposite side of the temporary support side into contact with a conductive layer in a substrate having a conductive layer to bond the transfer film and the substrate having a conductive layer.

In the manufacturing method of a circuit wiring according to the embodiment of the present invention, all of the photosensitive layer forming step, the first exposing step, the alkali developing step, and the second exposing step can be performed by the same procedure as in the step Y1, the step Y2A, the step Y3, and the step Y2B of the above-described pattern forming method of the embodiment 2. In addition, the substrate having a conductive layer, which is used in the manufacturing method of a circuit wiring according to the embodiment of the present invention, is the same as the substrate having a conductive layer, which is used in the above-described step X1. In addition, the manufacturing method of a circuit wiring according to the embodiment of the present invention may include a step other than the above-described steps. Examples of other steps include the same steps as the optional step which may be included in the pattern forming methods of the embodiment 1 and the embodiment 2.

In the manufacturing method of a circuit wiring according to the embodiment of the present invention, five steps of the above-described bonding step, the above-described first exposing step, the above-described developing step, the above-described second exposing step, and the above-described etching step are regarded as one set, and it is also preferable to repeat the set a plurality of times.

The film used as the etching resist film can also be used as a protective film (permanent film) for the formed circuit wiring.

[Manufacturing Method of Touch Panel]

The present invention also relates to a manufacturing method of a touch panel.

As long as it is a manufacturing method of a touch panel using the above-described photosensitive composition, the manufacturing method of a touch panel related to the present invention (also referred to as “manufacturing method of a touch panel according to the embodiment of the present invention) preferably includes, in the following order, a step (photosensitive layer forming step) of forming a photosensitive layer on a conductive layer (preferably, a patterned conductive layer; specifically, a touch panel electrode pattern or a conductive pattern such as a wiring line) in a substrate having the conductive layer using a photosensitive composition (preferably, the photosensitive composition of the aspect 3), a step (first exposing step) of exposing the photosensitive layer in a patterned manner, a step (alkali developing step) of developing the exposed photosensitive layer with an alkali developer to form a patterned photosensitive layer, and a step (second exposing step) of exposing the patterned photosensitive layer to form a protective film or an insulating film of the conductive layer.

The protective film formed by the second exposing step has a function as a film which protects the surface of the conductive layer. In addition, the insulating film has a function as an interlayer insulating film between conductive layers. In a case where the second exposing step is a step of forming an insulating film of the conductive layer, it is preferable that the manufacturing method of a touch panel according to the embodiment of the present invention further includes a step of forming a conductive layer (preferably, a patterned conductive layer; specifically, a touch panel electrode pattern or a conductive pattern such as a wiring line) on the insulating film formed by the second exposing step.

The above-described photosensitive layer forming step is also preferably a step (bonding step) of bringing a surface of the photosensitive layer in the above-described transfer film on an opposite side of the temporary support side into contact with a conductive layer in a substrate having a conductive layer to bond the transfer film and the substrate having a conductive layer.

In the manufacturing method of a touch panel according to the embodiment of the present invention, all of the photosensitive layer forming step, the first exposing step, the alkali developing step, and the second exposing step can be performed by the same procedure as in the step Y1, the step Y2A, the step Y3, and the step Y2B of the above-described pattern forming method of the embodiment 2. In addition, the substrate having a conductive layer, which is used in the manufacturing method of a touch panel according to the embodiment of the present invention, is the same as the substrate having a conductive layer, which is used in the above-described step X1. Examples of other steps include the same steps as the optional step which may be included in the pattern forming methods of the embodiment 1 and the embodiment 2.

As the manufacturing method of a touch panel according to the embodiment of the present invention, a known manufacturing method of a touch panel can be referred to for configurations other than those described above.

The touch panel manufactured by the manufacturing method of a touch panel according to the embodiment of the present invention preferably has a transparent substrate, an electrode, and a protective film (protective layer).

As a detection method in the touch panel, any known method such as a resistive film method, a capacitance method, an ultrasonic method, an electromagnetic induction method, and an optical method may be used. Among these, a capacitance method is preferable.

Examples of the touch panel type include an in-cell type (for example, those shown in FIGS. 5 to 8 of JP2012-517051A), an on-cell type (for example, one described in FIG. 19 of JP2013-168125A and those described in FIGS. 1 and 5 of JP2012-089102A), an one glass solution (OGS) type, a touch-on-lens (TOL) type (for example, one described in FIG. 2 of JP2013-054727A), other configurations (for example, those described in FIG. 6 of JP2013-164871A), and various out-cell types (GG, G1·G2, GFF, GF2, GF1, G1F, and the like).

### EXAMPLES

Hereinafter, the present invention will be described in detail with reference to Examples.

The material, the amount used, the proportion, the process contents, the process procedure, and the like shown in the following examples can be appropriately changed, within a range not departing from the gist of the present invention. Therefore, the scope of the present invention is not limited to the specific examples described below. “Part” and “%” are based on mass unless otherwise specified.

Unless otherwise specified, H03-L31 (manufactured by Eye Graphics Co., Ltd.) was used as a high-pressure mercury lamp in Examples. The above-described high-pressure mercury lamp has strong line spectrum at a wavelength of 254 nm, a wavelength of 313 nm, a wavelength of 405 nm, and a wavelength of 436 nm, with a wavelength of 365 nm as a main wavelength.

Unless otherwise specified, USH-2004 MB (manufactured by Ushio Inc.) was used as an ultra-high pressure mercury lamp in Examples. The above-described ultra-high pressure mercury lamp has strong line spectrum at a wavelength of 313 nm, a wavelength of 365 nm, a wavelength of 405 nm, and a wavelength of 436 nm.

[Each Component of Photosensitive Composition]

<Polymer A>

(Synthesis of Polymer A-1)

Under a nitrogen stream, propylene glycol monomethyl ether acetate (92 g) was heated to 90° C., and a solution in which styrene (150 g), a monomer a1-1 (88 g), and V-601 (polymerization initiator, manufactured by FUJIFILM Wako Pure Chemical Corporation) (5.5 g) were dissolved in propylene glycol monomethyl ether acetate (92 g) was added dropwise thereto over 2 hours. After the dropwise addition, V-601 (1.8 g) was additionally added thereto 3 times every 1 hour. Further, the obtained solution was reacted for 2 hours, and then diluted with propylene glycol monomethyl ether acetate (221 g) to obtain a solution including a polymer A-1 (concentration of solid contents: 36.3%). A residual rate of each monomer included in the polymer A-1 was less than 0.1% by mass with respect to the total solid content of the polymer. The residual rate of each monomer was measured by gas chromatography.

(Synthesis of Polymers A-2 to A-13, and A-15)

Polymers A-2 to A-13, and A-15 were each synthesized with reference to the synthesis procedure of the polymer A-1, thereby obtaining a solution including each of the polymers A-2 to A-13, and A-15 alone (concentration of solid contents: 36.3%, propylene glycol monomethyl ether acetate solution). Even in the polymers A-2 to A-13, and A-15, a residual rate of each monomer included in each polymer was less than 0.1% by mass with respect to the total solid content of the polymer. The residual rate of each monomer was measured by gas chromatography.

(Synthesis of Polymer A-14)

Under a nitrogen stream, propylene glycol monomethyl ether (158 g) was heated to 90° C., and a solution in which styrene (155 g), a monomer a1-2 (146 g), and V-601 (15 g) were dissolved in propylene glycol monomethyl ether (122 g) was added dropwise thereto over 2 hours. After the dropwise addition, V-601 (2.1 g) was additionally added thereto 3 times every 1 hour. Further, the obtained solution was reacted for 3 hours, and then diluted with propylene glycol monomethyl ether acetate (156 g) and propylene glycol monomethyl ether (143 g). Under an air stream, glycidyl methacrylate (Blemmer GH, manufactured by NOF Corporation) (43 g), tetraethylammonium bromide (1.5 g), and p-methoxyphenol (0.7 g) were added to the obtained solution, and a reaction was carried out at 100° C. for 7 hours to obtain a solution including a polymer A-14 (concentration of solid contents: 36.3%). A residual rate of each monomer included in the polymer A-14 was less than 0.1% by mass with respect to the total solid content of the polymer. The residual rate of each monomer was measured by gas chromatography.

The polymers A-1 to A-15 are shown below.

“Mw” indicates a weight-average molecular weight. “Mn” indicates a number-average molecular weight. The numerical value described together with each repeating unit indicates a mass ratio of each repeating unit. As monomers other than a monomer a shown below, commercially available products thereof were used.

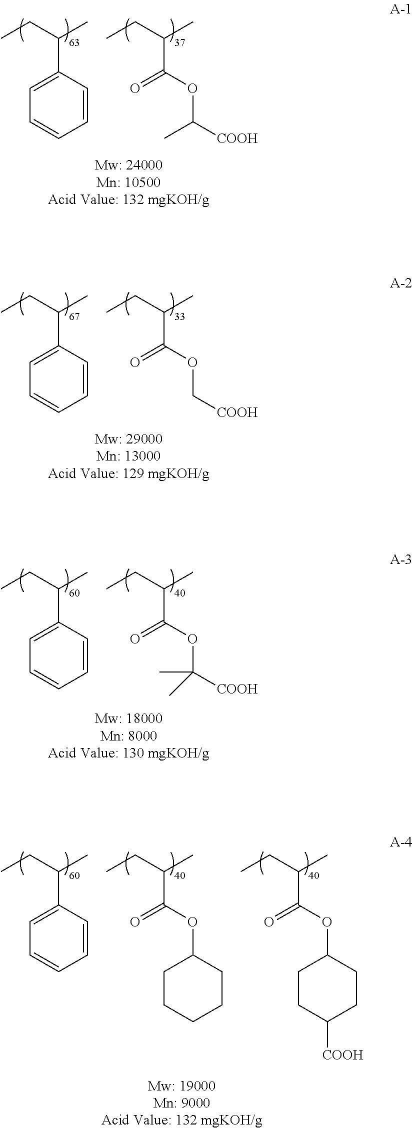

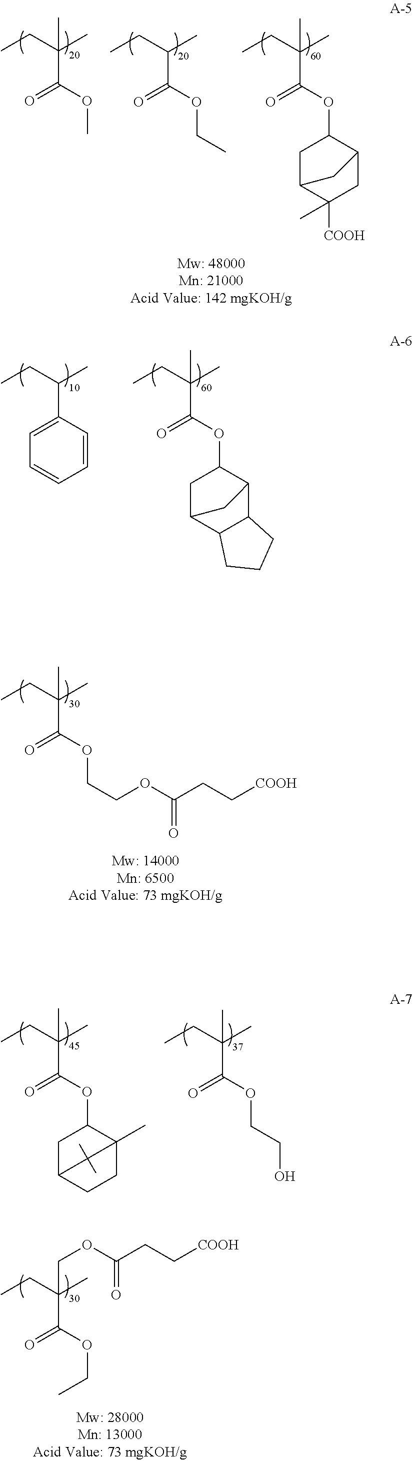

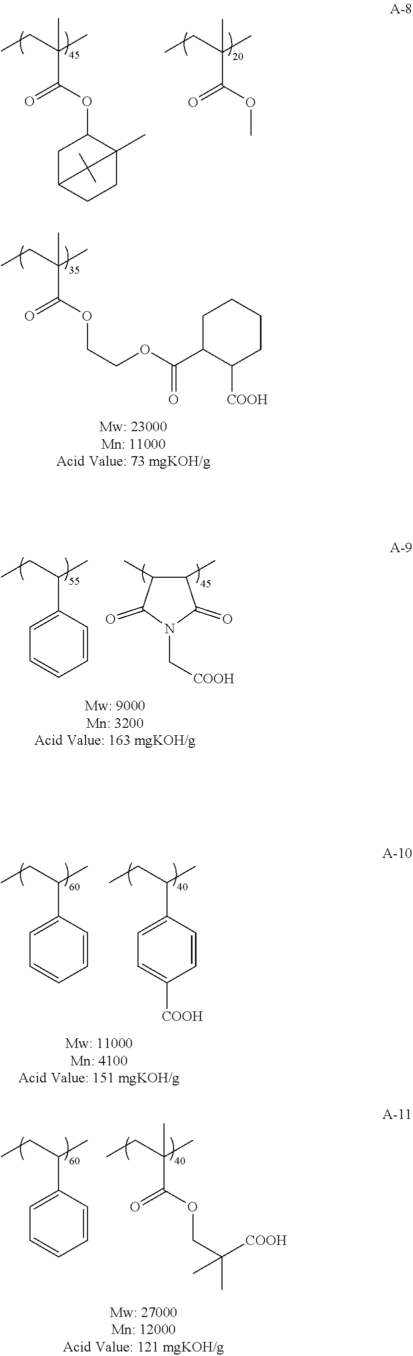

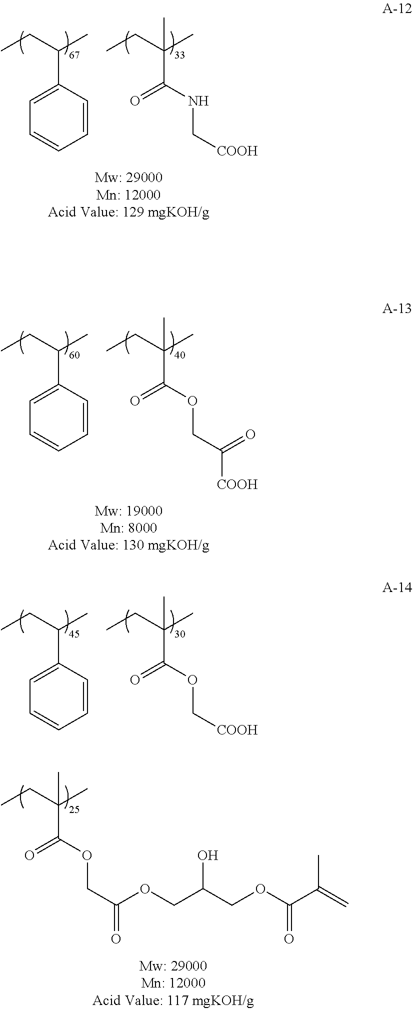

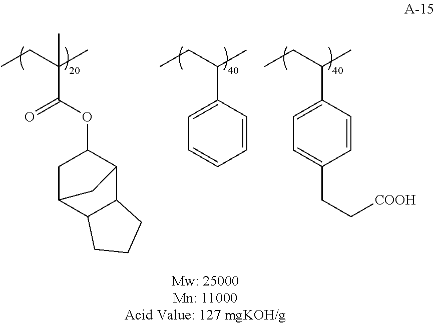

Each monomer a used as the repeating unit (a) of the polymer A was obtained by the following method.
a1-1 to a1-3: synthesis was carried out by the same method as that described in Example 2 of JP2016-23153A.
a1-4: synthesis was carried out by the method described in Example 4 of CN111056947.
a1-5: synthesis was carried out by the method described in Russian Journal of Applied Chemistry (2015), 88 (10), pp. 1733 to 1735.
a1-6: Light Ester HO-MS(N) (manufactured by Kyoeisha Chemical Co., Ltd.)
a1-7: Light Acrylate HOA-HH(N) (manufactured by Kyoeisha Chemical Co., Ltd.)
a1-8: synthesis was carried out by reacting ethyl α-hydroxymethylacrylate with succinic anhydride.
a1-9: synthesis was carried out by reacting maleic acid anhydride with glycine.
a1-10: manufactured by Tokyo Chemical Industry Co., Ltd.
a1-11: synthesis was carried out by reacting chloride methacrylate with glycine.
a1-12: synthesis was carried out by reacting methacrylic acid with methyl bromopyruvate, and hydrolyzing the terminal ester.
a1-13: synthesis was carried out by reacting chloride methacrylate with methyl hydroxypivalate, and hydrolyzing the terminal ester.
a1-14: synthesis was carried out by condensing chloromethylstyrene and dimethylmalonate under basic conditions, hydrolyzing methyl ester, and performing decarboxylation using copper oxide as a catalyst.

Each monomer a used as the repeating unit (a) of the polymer A is shown below.

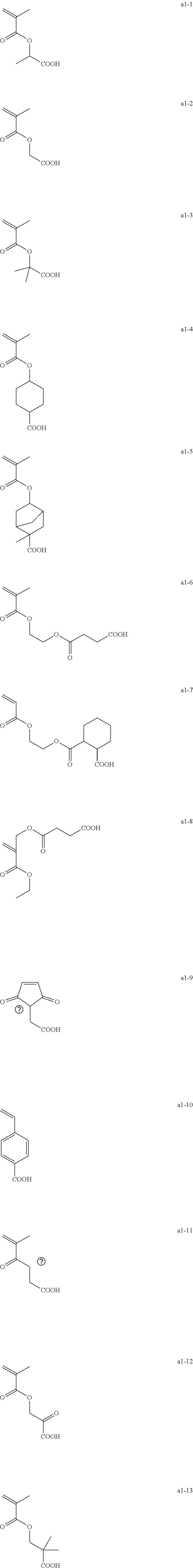

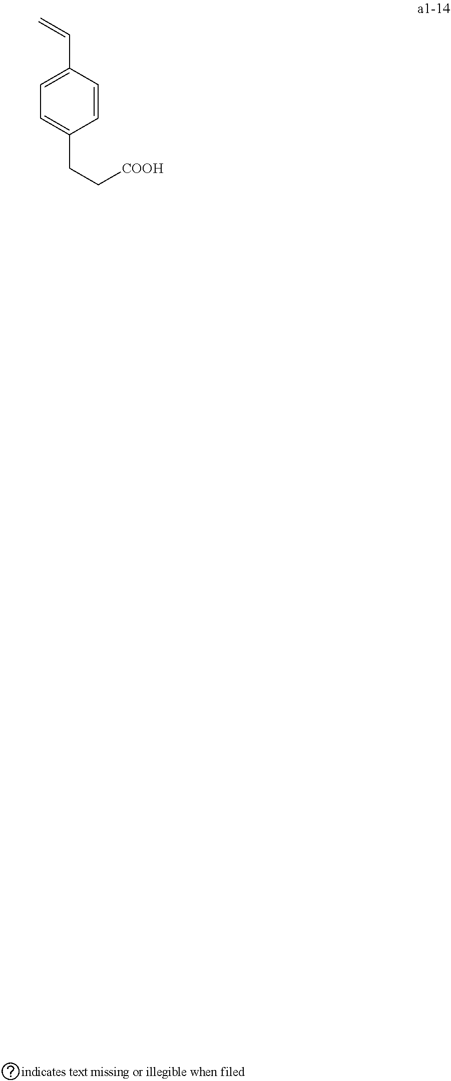

<Polymer X-1>

A polymer X-1 was synthesized with reference to the synthesis procedure of the polymer A-1. The polymer X-1 is shown below.

“Mw” indicates a weight-average molecular weight. “Mn” indicates a number-average molecular weight. The numerical value described together with each repeating unit indicates a mass ratio of each repeating unit.

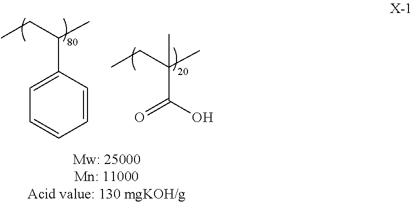

<Compound β>

A compound 3 is shown below.

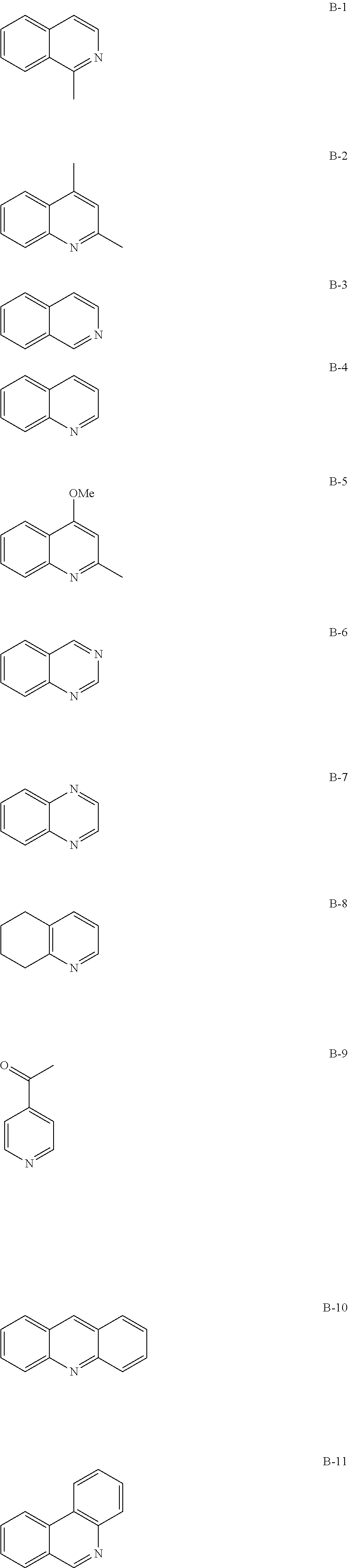

<Polymerizable Compound>
DPHA: dipentaerythritol hexaacrylate (A-DPH, manufactured by Shin-Nakamura Chemical Co., Ltd.)
A-NOD-N: 1,9-nonanediol diacrylate (A-NOD-N, manufactured by Shin-Nakamura Chemical Co., Ltd.)
DTMPT: ditrimethylolpropane tetraacrylate (KAYARAD T-1420 (T), manufactured by Nippon Kayaku Co., Ltd.)
A-DCPP: dicyclopentane dimethanol diacrylate (A-DCP, manufactured by Shin-Nakamura Chemical Co., Ltd.)
TMPT: trimethylolpropane triacrylate (A-TMPT, manufactured by Shin-Nakamura Chemical Co., Ltd.)
TO-2349: monomer having a carboxy group (ARONIX TO-2349, manufactured by Toagosei Co., Ltd.)

<Photopolymerization Initiator>
1 OXE-02: Irgacure OXE02 (oxime ester compound, manufactured by BASF SE)
OMN-379: Omnirad 379EG (aminoacetophenone compound, manufactured by IGM Resins B.V.)
Api-307: 1-(biphenyl-4-yl)-2-methyl-2-morpholinopropan-1-one (aminoacetophenone compound, manufactured by Shenzhen UV-ChemTech Co., Ltd.)
OMN-907: Omnirad 907 (aminoacetophenone compound, manufactured by IGM Resins B.V.)

<Metal Oxidation Inhibitor>
Benzimidazole

<Surfactant>

F551: MEGAFACE F551 (manufactured by DIC Corporation)
MEGAFACE R-41 (manufactured by DIC Corporation)
FTERGENT 710FL (manufactured by NEOS COMPANY LIMITED)

[Preparation of Photosensitive Composition]

Each component of the formulation described in tables below and a mixed solvent of propylene glycol monomethyl ether acetate/propylene glycol monomethyl ether/methyl ethyl ketone=18/60/22 (mass ratio) was mixed and stirred to prepare a photosensitive composition (concentration of solid contents in Examples 1 to 33 and Comparative Examples 1 to 3: 25% by mass, concentration of solid contents in Examples 34 to 38: 19% by mass). Numerical values corresponding to the components described in the tables below indicate parts by mass of the solid content. The solid content means all components in the composition, excluding a solvent (components forming a composition layer formed of the composition).

[Evaluation]

<Evaluation of Physical Properties of Compound β>

(Measurement of pKa of Compound β in Ground State)

The pKa of the compound β in a ground state was measured by the following method using an automatic titrator manufactured by HIRANUMA Co., Ltd. In a case where the compound β was a nitrogen-containing aromatic compound, the pKa of the compound β in a ground state was intended to be a pKa of a conjugate acid of the compound p.

0.1 g of the compound β was dissolved in 20 mL of methanol, and 20 mL of ultrapure water was added thereto. This mixture was titrated using a 0.1 N—HCL aqueous solution, and the pH at ½ of the titration amount required up to the equivalence point was defined as the pKa (pKa of the compound β in a ground state).

(Measurement and Evaluation of ε₃₆₅ and ε₃₆₅/ε₃₁₃)

A molar absorption coefficient ε₃₆₅ ((cm·mol/L)⁻¹) of the compound β at a wavelength of 365 nm and a molar absorption coefficient ε₃₁₃ ((cm·mol/L)⁻¹) of the compound β at a wavelength of 313 nm were obtained, and a value (ε₃₆₅/ε₃₁₃) obtained by divided ε₃₆₅ by ε₃₁₃ was obtained.

The ε₃₆₅ and ε₃₁₃ of the compound β are molar absorption coefficients measured by dissolving the compound β in acetonitrile. In a case where the compound β was insoluble in acetonitrile, a solvent for dissolving the compound 3 may be appropriately changed.

<Decarboxylation Rate>

A decarboxylation rate was determined from a carboxy group amount of the photosensitive composition before exposure (carboxy group amount before exposure) and a carboxy group amount of the photosensitive layer after exposure (carboxy group amount after exposure), according to the following procedure.

(Carboxy Group Amount of Photosensitive Composition Before Exposure)

According to the following procedure, the carboxy group amount of the photosensitive composition before exposure in Examples and Comparative Examples, which was used for forming the following photosensitive layer, was measured.

The photosensitive composition (1 g) was dissolved in tetrahydrofuran (63 mL), and ultrapure water (12 mL) was added thereto. Next, the obtained solution was titrated with a 0.1 N—NaOH aqueous solution using an automatic titrator (manufactured by HIRANUMA Co., Ltd.). The carboxy group amount of the photosensitive composition before exposure was calculated by converting the carboxy group amount obtained by the titration into a concentration of solid contents.

(Carboxy Group Amount of Photosensitive Layer after Exposure)

To a polyethylene terephthalate film (16KS40, manufactured by Toray Industries, Inc.) having a thickness of 16 μm (temporary support), any one of the photosensitive compositions in Examples and Comparative Examples was applied using a slit-shaped nozzle such that a thickness after drying was adjusted to 8.0 μm, and the photosensitive composition was dried at 100° C. for 2 minutes to form a photosensitive layer. A polyethylene terephthalate film (manufactured by Toray Industries, Inc., 16KS40) having a thickness of 16 μm (cover film) was pressure-bonded onto the photosensitive layer. Accordingly, a transfer film A including the photosensitive layer and the cover film in this order was produced on the temporary support.

By peeling off the cover film from the produced transfer film A and laminating the transfer film on a glass substrate, the photosensitive layer of the transfer film was transferred to a surface of the glass substrate to obtain a laminate A having a laminated structure of “temporary support/photosensitive layer/substrate (glass)”. Laminating conditions were that a temperature of the substrate was 40° C., a temperature of a rubber roller (a laminating temperature) was 110° C., a linear pressure was 3 N/cm, and a transportation speed was 2 m/min. The laminating property was good.

The temporary support was peeled off from the obtained laminate A, and the photosensitive layer was entirely exposed using a high-pressure mercury lamp (H03-L31, manufactured by Eye Graphics Co., Ltd.). An integrated exposure amount measured with a 365 nm wavelength illuminance meter was 1,000 mJ/cm². Light emitted from the above-described high-pressure mercury lamp has strong line spectrum at a wavelength of 254 nm, a wavelength of 313 nm, a wavelength of 405 nm, and a wavelength of 436 nm, with a wavelength of 365 nm as a main wavelength.

Next, approximately 20 mg of the photosensitive layer after the exposure was scraped off, and frozen and pulverized, N-methyl-2-pyrrolidone (150 μL) was added thereto, and the mixture was stirred in an aqueous solution of lithium carbonate (Li₂CO₃) (1.2 g/100 mL; lithium carbonate was dissolved in ultrapure water and then filtered through a filter) for 6 days.

The solution after completion of the stirring was subjected to ultracentrifugation treatment causing precipitation of particles under the conditions of 140,000 rpm and 30 minutes, and the supernatant was replaced with ultrapure water. The replacement was repeated 5 times, and the obtained precipitate was dried to dryness and used as an analysis sample (production of a sample in which n=2). The obtained analysis sample was analyzed by ICP-OES (Optima 7300DV, manufactured by PerkinElmer Inc.). The ICP-OES measurement was carried out according to the following procedure.

The above-described analytical sample (approximately 1.5 mg to 2.0 mg) was weighed (n=3), a 60% HNO₃ aqueous solution (5 mL) was added thereto, and MW Teflon ashing (microwave sample decomposition device UltraWAVE max: 260° C.) was performed.

After the above-described carbonization, ultrapure water was added to the obtained sample to be a total volume of 50 mL. The amount of lithium was quantified by an absolute calibration curve method using ICP-OES (Optima 7300DV, manufactured by PerkinElmer Inc.). The carboxy group amount of the photosensitive layer after exposure was quantified by quantifying amounts of carboxy group and ion-bonded lithium.

(Calculation of Decarboxylation Rate)

Based on the measurement results of the carboxy group amounts before the exposure and after the exposure described above, a decarboxylation rate was calculated by the following expression.

Decarboxylation rate(mol %)={(Carboxy group amount before exposure−Carboxy group amount after exposure)/Carboxy group amount before exposure}×100

In a case where the decarboxylation rates of Examples and Comparative Examples were measured according to the above-described procedure, the decarboxylation rates of Examples and Comparative Example 1 were all 40 to 70 mol %, and it was confirmed that decarboxylation proceeded. In addition, no progress of the decarboxylation was observed in Comparative Examples 2 and 3 (the decarboxylation rate was 0 mol %).

<Low Moisture Permeability (WVTR)>

(Production of Sample for Measuring Moisture Permeability)

To a polyethylene terephthalate (PET) film having a thickness of 75 μm (temporary support), any one of the photosensitive compositions in Examples and Comparative Examples was applied using a slit-shaped nozzle, and the photosensitive composition was dried to form a photosensitive layer having a thickness of 8.0 μm, thereby obtaining a transfer film B.

Next, the obtained transfer film B was laminated on PTFE (tetrafluoroethylene resin) membrane filter (FP-100-100, manufactured by Sumitomo Electric Industries, Ltd.), to form a laminate B1 having a laminated structure of “temporary support/photosensitive layer having a thickness of 8.0 μm/membrane filter”. Laminating conditions were that a temperature of the membrane filter was 40° C., a temperature of a rubber roller (that is, a laminating temperature) was 110° C., a linear pressure was 3 N/cm, and a transportation speed was 2 m/min. The laminating property was good.

Next, the temporary support was peeled off from the laminate B1. A procedure in which, on the exposed photosensitive layer of the laminate B1 from which the temporary support had been peeled off, the surface of the photosensitive layer of the transfer film B opposite to the temporary support was further laminated under the same laminating conditions as described above, and the temporary support was peeled off from the obtained laminate was repeated 4 times to obtain a laminate B2 having a laminated structure of “photosensitive layer having a total thickness of 40 μm/membrane filter”. The photosensitive layer of the obtained laminate B2 was entirely exposed using a high-pressure mercury lamp (H03-L31, manufactured by Eye Graphics Co., Ltd.). An integrated exposure amount measured with a 365 nm wavelength illuminance meter was 1,000 mJ/cm². Accordingly, a laminate B3 (sample for measuring moisture permeability) having a laminated structure of “exposed photosensitive layer having a total film thickness of 40 μm/membrane filter” was obtained.

(Measurement of Moisture Permeability (WVTR))

The measurement of the moisture permeability was performed by a cup method using the above-described sample for measuring moisture permeability, with reference to JIS-Z-0208 (1976).

A circular sample having a diameter of 70 mm was cut from the above-described sample for measuring moisture permeability. Next, dried calcium chloride (20 g) was put in a measurement cup, and lidded with the circular sample, and accordingly, a measurement cup with lid was prepared.

The above-described measurement cup with lid was left in a constant-temperature and constant-humidity tank for 24 hours under the condition of 75° C. with 90% RH. A water vapor transmission rate (WVTR) of the circular sample (g/(m² day)) was calculated from a change in mass of the measurement cup with lid before and after the leaving.

The measurement described above was performed three times and an average value of the WVTRs in three times of the measurement was calculated.

A low moisture permeability was evaluated based on the reduction rate (%) of the WVTR in Examples and other Comparative Examples, in a case where the WVTR of Comparative Example 3 was set to 100%. As the value of the reduction rate is larger, the moisture permeability was further lowered as compared with Comparative Example 3, which is preferable as a protective film. In the following evaluation standard, A or B is preferable, and A is more preferable.

In the above-described measurement, the WVTR of the above-described circular sample having a laminated structure of “exposed photosensitive layer having a total thickness of 40 μm/membrane filter” was measured. However, the WVTR of the membrane filter is extremely higher than the WVTR of the exposed photosensitive layer, and accordingly, in the above-described measurement, the WVTR of the exposed photosensitive layer is substantially measured.
A: reduction rate of the WVTR was 30% or more.
B: reduction rate of the WVTR was 20% or more and less than 30%.
C: reduction rate of the WVTR was 10% or more and less than 20%.
D: reduction rate of the WVTR was 5% or more and less than 10%.
E: reduction rate of the WVTR was less than 5%.

<Pencil Hardness (Scratch Resistance)>

(Production of Sample for Measuring Pencil Hardness)

Transfer films C of Examples and Comparative Examples were produced in the same manner as in the transfer film A described above, except that the thickness of the photosensitive layer after drying was adjusted to be 4.0 μm.

By peeling off the cover film from the produced transfer film C and laminating the transfer film C on a glass substrate (ITO base material) laminated with an ITO layer, the photosensitive layer of the transfer film C was transferred to a surface of the ITO layer to obtain a laminate C having a laminated structure of “temporary support/photosensitive layer/ITO layer/substrate (glass)”. Laminating conditions were that a temperature of the ITO substrate was 40° C., a temperature of a rubber roller (that is, a laminating temperature) was 110° C., a linear pressure was 3 N/cm, and a transportation speed was 2 m/min. The laminating property was good. Here, the ITO base material is a base material assuming an electrode substrate of a touch panel.

(Measurement of Pencil Hardness)

The obtained laminate C was exposed through the temporary support using a proximity type exposure machine (manufactured by Hitachi High-Tech Electronics Engineering Co., Ltd.) including an ultra-high pressure mercury lamp in a patterned manner with a 7 cm×7 cm square. The temporary support was peeled off from the exposed laminate C, and the exposed laminate C was subjected to shower development at 33° C. for 45 seconds using a 1% by mass sodium carbonate aqueous solution, and then rinsed with pure water for 25 seconds. A cured pattern without film burr was obtained in the exposed portion, the non-exposed portion was removed by development, and no residue was observed. Next, the entire surface was post-exposed using a high-pressure mercury lamp. An exposure amount observed with a 365 nm illuminance meter was 1,000 mJ/cm². Accordingly, a cured film pattern was formed on the ITO base material.

A pencil hardness test was performed on the obtained cured film pattern by a method based on “JIS K5600-5-4”, and the pencil hardness was defined as the hardness of the hardest pencil which did not cause scars. A pencil hardness of 2H or more has the best scratch resistance, and the order of improvement is H, HB, B, and 2B or less.
A: pencil hardness was 2H or more.
B: pencil hardness was H.
C: pencil hardness was HB.
D: pencil hardness was B.
E: pencil hardness was 2B or less.

TABLE 2

| | | Example | | | | | | | | |
|---|---|---|---|---|---|---|---|---|---|---|
| | | 1 | 2 | 3 | 4 | 5 | 6 | 7 | 8 | 9 |
| Polymer A | Type | A-1 | A-2 | A-3 | A-4 | A-5 | A-6 | A-7 | A-8 | A-9 |
| | | 57.6 | 57.6 | 57.6 | 57.6 | 57.6 | 57.6 | 57.6 | 57.6 | 57.6 |
| | X in Formula (a1) | A | A | A | A | A | A | A | A | B |
| | Alkylene group A | A | A | A | A | A | B | A | B | B |
| Compound β | Type | B-1 | B-1 | B-1 | B-1 | B-1 | B-1 | B-1 | B-1 | B-1 |
| | Part by mass | 3.8 | 3.8 | 3.8 | 3.8 | 3.8 | 3.8 | 3.8 | 3.8 | 3.8 |
| | ε₃₆₅ (cm · mol/L)⁻¹ | <10 | <10 | <10 | <10 | <10 | <10 | <10 | <10 | <10 |
| | ε₃₆₅/ε₃₁₃ | <1 | <1 | <1 | <1 | <1 | <1 | <1 | <1 | <1 |
| | pKa | 5.31 | 5.31 | 5.31 | 5.31 | 5.31 | 5.31 | 5.31 | 5.31 | 5.31 |
| | Substituent | A | A | A | A | A | A | A | A | A |
| Polymerizable | DPHA | 10.6 | 10.6 | 10.6 | 10.6 | 10.6 | 10.6 | 10.6 | 10.6 | 10.6 |
| compound | A-NOD-N | 23.1 | 23.1 | 23.1 | 23.1 | 23.1 | 23.1 | 23.1 | 23.1 | 23.1 |
| | DTMPT | | | | | | | | | |
| | A-DCP | | | | | | | | | |
| | TMPT | | | | | | | | | |
| | TO-2349 | 3.2 | 3.2 | 3.2 | 3.2 | 3.2 | 3.2 | 3.2 | 3.2 | 3.2 |
| Photopolymerization | OXE-02 | | | | | | | | | |
| initiator | OMN-379 | 0.3 | 0.3 | 0.3 | 0.3 | 0.3 | 0.3 | 0.3 | 0.3 | 0.3 |
| | Api-307 | 0.9 | 0.9 | 0.9 | 0.9 | 0.9 | 0.9 | 0.9 | 0.9 | 0.9 |
| | OMN-907 | | | | | | | | | |
| Metal oxidation | Benzimidazole | 0.3 | 0.3 | 0.3 | 0.3 | 0.3 | 0.3 | 0.3 | 0.3 | 0.3 |
| inhibitor | | | | | | | | | | |
| Surfactant | F551 | 0.2 | 0.2 | 0.2 | 0.2 | 0.2 | 0.2 | 0.2 | 0.2 | 0.2 |
| Evaluation result | Low moisture | A | A | A | A | A | A | A | A | B |
| | permeability | | | | | | | | | |
| | Scratch resistance | A | A | A | A | A | B | A | B | A |

| | | Example | | | | | | Comparative Example | | |
|---|---|---|---|---|---|---|---|---|---|---|
| | | 10 | 11 | 12 | 13 | 14 | 15 | 1 | 2 | 3 |
| Polymer A | Type | A-10 | A-11 | A-12 | A-13 | A-14 | A-15 | X-1 | A-1 | X-1 |
| | | 57.6 | 57.6 | 57.6 | 57.6 | 57.6 | 57.6 | 57.6 | 61.4 | 61.4 |
| | X in Formula (a1) | A | A | B | B | A | A | | A | |
| | Alkylene group A | A | A | B | B | A | A | | A | |
| Compound β | Type | B-1 | B-1 | B-1 | B-1 | B-1 | B-1 | B-1 | | |
| | Part by mass | 3.8 | 3.8 | 3.8 | 3.8 | 3.8 | 3.8 | 3.8 | | |
| | ε₃₆₅ (cm · mol/L)⁻¹ | <10 | <10 | <10 | <10 | <10 | <10 | <10 | | |
| | ε₃₆₅/ε₃₁₃ | <1 | <1 | <1 | <1 | <1 | <1 | <1 | | |
| | pKa | 5.31 | 5.31 | 5.31 | 5.31 | 5.31 | 5.31 | 5.31 | | |
| | Substituent | A | A | A | A | A | A | A | | |
| Polymerizable | DPHA | 10.6 | 10.6 | 10.6 | 10.6 | 10.6 | 10.6 | 10.6 | 10.6 | 10.6 |
| compound | A-NOD-N | 23.1 | 23.1 | 23.1 | 23.1 | 23.1 | 23.1 | 23.1 | 23.1 | 23.1 |
| | DTMPT | | | | | | | | | |
| | A-DCP | | | | | | | | | |
| | TMPT | | | | | | | | | |
| | TO-2349 | 3.2 | 3.2 | 3.2 | 3.2 | 3.2 | 3.2 | 3.2 | 3.2 | 3.2 |
| Photopolymerization | OXE-02 | | | | | | | | | |
| initiator | OMN-379 | 0.3 | 0.3 | 0.3 | 0.3 | 0.3 | 0.3 | 0.3 | 0.3 | 0.3 |
| | Api-307 | 0.9 | 0.9 | 0.9 | 0.9 | 0.9 | 0.9 | 0.9 | 0.9 | 0.9 |
| | OMN-907 | | | | | | | | | |
| Metal oxidation | Benzimidazole | 0.3 | 0.3 | 0.3 | 0.3 | 0.3 | 0.3 | 0.3 | 0.3 | 0.3 |
| inhibitor | | | | | | | | | | |
| Surfactant | F551 | 0.2 | 0.2 | 0.2 | 0.2 | 0.2 | 0.2 | 0.2 | 0.2 | 0.2 |
| Evaluation result | Low moisture | A | A | B | B | A | A | C | E | Reference |
| | permeability | | | | | | | | | |
| | Scratch resistance | A | A | A | A | A | A | E | C | C |

TABLE 3

| | | Example | | | | | | | | | |
|---|---|---|---|---|---|---|---|---|---|---|---|
| | | 16 | 17 | 18 | 19 | 20 | 21 | 22 | 23 | 24 | 25 |
| Polymer A | Type | A-1 | A-1 | A-1 | A-1 | A-1 | A-1 | A-1 | A-1 | A-1 | A-1 |
| | | 57.6 | 57.6 | 57.6 | 57.6 | 57.6 | 57.6 | 57.6 | 57.6 | 57.6 | 57.6 |
| | X in Formula (a1) | A | A | A | A | A | A | A | A | A | A |
| | Alkylene group A | A | A | A | A | A | A | A | A | A | A |
| Compound β | Type | B-2 | B-3 | B-4 | B-5 | B-6 | B-7 | B-8 | B-9 | B-10 | B-11 |
| | Part by mass | 3.8 | 3.8 | 3.8 | 3.8 | 3.8 | 3.8 | 3.8 | 3.8 | 3.8 | 3.8 |
| | ε₃₆₅ (cm · mol/L)⁻¹ | <10 | <10 | <10 | <10 | 160 | 190 | <10 | <10 | 4900 | 500 |
| | ε₃₆₅/ε₃₁₃ | <1 | <1 | <1 | <1 | <1 | <1 | <1 | <1 | >3 | <1 |
| | pKa | 5.7 | 4.7 | 4.2 | 6.5 | 4.0 | 2.4 | 5.9 | 3.1 | 4.7 | 3.8 |
| | Substituent | A | B | B | A | B | B | A | A | B | B |
| Polymerizable | DPHA | 10.6 | 10.6 | 10.6 | 10.6 | 10.6 | 10.6 | 10.6 | 10.6 | 10.6 | 10.6 |
| compound | A-NOD-N | 23.1 | 23.1 | 23.1 | 23.1 | 23.1 | 23.1 | 23.1 | 23.1 | 23.1 | 23.1 |
| | DTMPT | | | | | | | | | | |
| | A-DCP | | | | | | | | | | |
| | TMPT | | | | | | | | | | |
| | TO-2349 | 3.2 | 3.2 | 3.2 | 3.2 | 3.2 | 3.2 | 3.2 | 3.2 | 3.2 | 3.2 |
| Photopolymerization | OXE-02 | | | | | | | | | | |
| initiator | OMN-379 | 0.3 | 0.3 | 0.3 | 0.3 | 0.3 | 0.3 | 0.3 | 0.3 | 0.3 | 0.3 |
| | Api-307 | 0.9 | 0.9 | 0.9 | 0.9 | 0.9 | 0.9 | 0.9 | 0.9 | 0.9 | 0.9 |
| | OMN-907 | | | | | | | | | | |
| Metal oxidation | Benzimidazole | 0.3 | 0.3 | 0.3 | 0.3 | 0.3 | 0.3 | 0.3 | 0.3 | 0.3 | 0.3 |
| inhibitor | | | | | | | | | | | |
| Surfactant | F551 | 0.2 | 0.2 | 0.2 | 0.2 | 0.2 | 0.2 | 0.2 | 0.2 | 0.2 | 0.2 |
| | R-14 | | | | | | | | | | |
| | 710FL | | | | | | | | | | |
| Evaluation result | Low moisture | A | A | A | A | A | A | A | A | B | A |
| | permeability | | | | | | | | | | |
| | Scratch resistance | A | B | B | A | B | B | B | B | B | B |

TABLE 4

| | | Example | | | | | | | | | | | | |
|---|---|---|---|---|---|---|---|---|---|---|---|---|---|---|
| | | 26 | 27 | 28 | 29 | 30 | 31 | 32 | 33 | 34 | 35 | 36 | 37 | 38 |
| Polymer A | Type | A-11 | A-11 | A-11 | A-11 | A-11 | A-11 | A-11 | A-11 | A-1 | A-11 | A-11 | A-11 | A-5 |
| | | 57.6 | 57.6 | 57.6 | 57.6 | 70.0 | 48.5 | 45.0 | 45.0 | 57.8 | 57.9 | 48.5 | 45.0 | 58.0 |
| | X in Formula (a1) | A | A | A | A | A | A | A | A | A | A | A | A | A |
| | Alkylene group A | A | A | A | A | A | A | A | A | A | A | A | A | A |
| Compound β | Type | B-1 | B-1 | B-1 | B-1 | B-1 | B-1 | B-1 | B-1 | B-1 | B-1 | B-1 | B-1 | B-1 |
| | Part by mass | 3.8 | 3.8 | 3.8 | 3.8 | 1.0 | 2.5 | 6.0 | 8.0 | 3.8 | 3.8 | 2.5 | 6.0 | 3.8 |
| | ε₃₆₅ (cm · mol/L)⁻¹ | <10 | <10 | <10 | <10 | <10 | <10 | <10 | <10 | <10 | <10 | <10 | <10 | <10 |
| | ε₃₆₅/ε₃₁₃ | <1 | <1 | <1 | <1 | <1 | <1 | <1 | <1 | <1 | <1 | <1 | <1 | <1 |
| | pKa | 5.3 | 5.3 | 5.3 | 5.3 | 5.3 | 5.3 | 5.3 | 5.3 | 5.31 | 5.3 | 5.3 | 5.3 | 5.31 |
| | Substituent | A | A | A | A | A | A | A | A | A | A | A | A | A |
| Polymerizable | DPHA | 10.6 | | 10.6 | 10.6 | 5.0 | 21.0 | 21.0 | 21.0 | 10.0 | | 21.0 | 21.5 | 13.8 |
| compound | A-NOD-N | | 10.0 | 23.1 | 23.1 | 19.1 | 23.1 | 23.1 | 21.1 | 23.1 | 10.0 | 23.5 | 23.1 | 23.1 |
| | DTMPT | | 13.7 | | | | | | | | 13.7 | | | |
| | A-DCP | 23.1 | | | | | | | | | | | | |
| | TMPT | | 10.0 | | | | | | | | 10.0 | | | |
| | TO-2349 | 3.2 | 3.2 | 3.2 | 3.2 | 3.2 | 3.2 | 3.2 | 3.2 | 3.8 | 3.2 | 3.2 | 3.2 | |
| Photopolymerization | OXE-02 | | | 0.3 | 0.3 | | | | | | | | 0.2 | |
| initiator | OMN-379 | 0.3 | 0.3 | | | 0.3 | 0.3 | 0.3 | 0.3 | 0.4 | 0.3 | 0.3 | | 0.3 |
| | Api-307 | 0.9 | 0.9 | | 0.9 | 0.9 | 0.9 | 0.9 | 0.9 | 1.0 | 0.9 | 0.9 | | 0.9 |
| | OMN-907 | | | 0.9 | | | | | | | | | 0.8 | |
| Metal oxidation | Benzimidazole | 0.3 | 0.3 | 0.3 | 0.3 | 0.3 | 0.3 | 0.3 | 0.3 | | | | | |
| inhibitor | | | | | | | | | | | | | | |
| Surfactant | F551 | 0.2 | 0.2 | 0.2 | 0.2 | 0.2 | 0.2 | 0.2 | 0.2 | 0.1 | | | | |
| | R-14 | | | | | | | | | | 0.2 | 0.1 | | |
| | 710FL | | | | | | | | | | | | 0.2 | 0.1 |
| Evaluation result | Low moisture | A | A | A | A | A | A | A | B | A | A | A | A | A |
| | permeability | | | | | | | | | | | | | |
| | Scratch resistance | A | A | A | A | B | A | A | A | A | A | A | A | A |

In the tables, each description indicates the following.

In the column of “X in Formula (a1)”, a case where X in Formula (a1) represents an alkylene group, a cycloalkylene group, an arylene group, —COO—, or a group of a combination of these groups is designated as “A”, and the other cases are designated as “B”.

In the column of “Alkylene group A”, a case where the linking group having 1 or more carbon atoms in each polymer A corresponds to the alkylene group A described above is designated as “A”, and a case of not corresponding to the alkylene group A described above is designated as “B”.

The column of “ε₃₆₅ (cm·mol/L)⁻¹” indicates a molar absorption coefficient ε₃₆₅ (cm·mol/L)⁻¹ of the compound β to light having a wavelength of 365 nm. The molar absorption coefficient ε₃₆₅ is a value in acetonitrile.

The column of “ε₃₆₅/ε₃₁₃” indicates a value obtained by dividing the molar absorption coefficient ε₃₆₅ (cm·mol/L)⁻¹ of the compound β to light having a wavelength of 365 nm by the molar absorption coefficient ε₃₁₃ (cm·mol/L)⁻¹ of the compound β to light having a wavelength of 313 nm. All molar absorption coefficients are values in acetonitrile.

The column of “pKa” indicates pKa of the above-described compound 3 in a ground state.

In the column of “substituent”, a case where the compound 3 has a substituent is designated as “A”, and the other cases are designated as “B”.

From the results shown in the above tables, it was confirmed that the transfer film according to the embodiment of the present invention could obtain the effect of the present invention.

In a case where X in Formula (a1) represented an alkylene group, a cycloalkylene group, an arylene group, —COO—, or a group of a combination of these groups, it was confirmed that the effect of the present invention was more excellent (comparison of Examples 1 to 15).

In a case where the linking group having 1 or more carbon atoms, included in the polymer A, was the alkylene group A, it was confirmed that the scratch resistance was more excellent (comparison of Examples 1 to 5, 7, 10, 11, 14, 15, 6, and 8).

In a case where the compound 3 included one or more selected from the group consisting of a monocyclic aromatic compound and a compound in which two rings are fused to form an aromatic ring, it was confirmed that the low moisture permeability was more excellent (comparison of Examples 1, 16 to 23, 24, and 25). In addition, in a case where the compound β included one or more selected from the group consisting of a quinoline derivative (quinoline having a substituent) and an isoquinoline derivative (isoquinoline having a substituent), it was confirmed that the scratch resistance was even more excellent (comparison of Examples 1, and 16 to 23).

In a case where the ratio of the molar absorption coefficient ε₃₆₅ of the compound β at a wavelength of 365 nm to the molar absorption coefficient ε₃₁₃ of the compound β at a wavelength of 313 nm was 3 or less, it was confirmed that the low moisture permeability was more excellent (comparison of Examples 1, 16 to 23, 25, 26, and 24).

In a case where the photosensitive layer further contained a polymerizable compound and a photopolymerization initiator (corresponding to the transfer film of the aspect 3), and the content of the compound 3 (preferably, the compound B) was 1.5% to 7.5% by mass with respect to the total solid content of the photosensitive composition, it was confirmed that the effect of the present invention was more excellent (comparison of Examples 30 to 33).

[Production of Transfer Film D]

<Formation of Photosensitive Layer (First Layer)>

To a polyethylene terephthalate film (16KS40, manufactured by Toray Industries, Inc.) having a thickness of 16 μm (temporary support), each photosensitive composition shown in the above tables was applied using a slit-shaped nozzle such that a thickness after drying was adjusted to 8.0 μm, and the photosensitive composition was dried at 100° C. for 2 minutes to form a photosensitive layer (first layer).

<Formation of Layer of High Refractive Index (Second Layer)>

Next, a composition for forming a layer of high refractive index, having the following formulation 201, was applied to the photosensitive layer such that a thickness after drying was adjusted to 70 nm, dried for 1 minute at 80° C., and further dried for 1 minute at 110° C. to form a layer of high refractive index (second layer). A refractive index of the layer of high refractive index was 1.68.

In the formulation 201, since a resin having an acid group and an ammonia aqueous solution were used, the resin having an acid group was neutralized with the ammonia aqueous solution. That is, the composition for forming the layer of high refractive index contained an ammonium salt of the resin having an acid group.

(Formulation 201)
Acrylic resin (resin having an acid group, copolymer resin of methacrylic acid/allyl methacrylate, weight-average molecular weight: 25,000, compositional ratio (molar ratio)=40/60):0.29 parts
ARONIX TO-2349 (monomer having a carboxy group, manufactured by Toagosei Co., Ltd.): 0.04 parts
NanoUse OZ-S30M (ZrO₂ particles, concentration of solid contents: 30.5%, methanol 69.5%, refractive index: 2.2, average particle diameter: approximately 12 nm, manufactured by Nissan Chemical Corporation): 4.80 parts
BT120 (benzotriazole, manufactured by JOHOKU CHEMICAL CO., LTD.): 0.03 parts
MEGAFACE F444 (fluorine-based surfactant, manufactured by DIC Corporation): 0.01 parts
Ammonia aqueous solution (2.5%): 7.80 parts
Distilled water: 24.80 parts
Methanol: 76.10 parts

A polyethylene terephthalate film (manufactured by Toray Industries, Inc., 16KS40) having a thickness of 16 μm (cover film) was pressure-bonded onto the layer of high refractive index in a laminate D having a laminated structure “temporary support/photosensitive layer/layer of high refractive index” obtained as described above. Accordingly, a transfer film D including the photosensitive layer, the layer of high refractive index, and the cover film was produced on the temporary support.

In a case where each transfer film D was used and evaluated in the same manner as in <Low moisture permeability (WVTR)> and <Scratch resistance> described above, the same results as the evaluation of each transfer film B and each transfer film C were obtained.

### EXPLANATION OF REFERENCES

12: temporary support
14: photosensitive layer
16: cover film
100: transfer film

What is claimed is:

1. A transfer film comprising:
a temporary support; and
a photosensitive layer,
wherein the photosensitive layer contains a polymer A and a compound 3,
the polymer A has a repeating unit (a) having a carboxy group linked to a main chain by a linking group having 1 or more carbon atoms, and
the compound β has a structure b0 which reduces an amount of the carboxy group included in the polymer A by exposure.

2. The transfer film according to claim 1,
wherein the repeating unit (a) has one or more selected from the group consisting of a repeating unit represented by Formula (a1) and a repeating unit represented by Formula (a2), 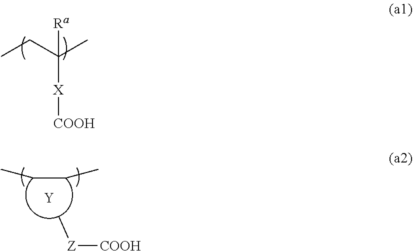
in Formula (a1), R^{a} represents a hydrogen atom or a substituent, and X represents a linking group having 1 or more carbon atoms,
in Formula (a2), Y represents a ring group, Z represents a single bond or a linking group, and at least one of Y or Z represents a group having 1 or more carbon atoms.

3. The transfer film according to claim 2,
wherein X in Formula (a1) represents an alkylene group, a cycloalkylene group, an arylene group, —COO—, or a group of a combination of these groups.

4. The transfer film according to claim 2,
wherein the repeating unit represented by Formula (a1) has a repeating unit represented by Formula (a1-1), 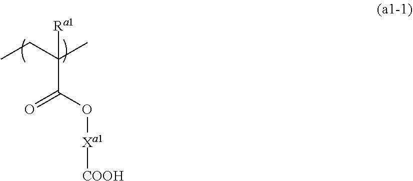
in Formula (a1-1), R^{a1} represents a hydrogen atom or a methyl group, and X^{a1} represents a linking group.

5. The transfer film according to claim 4,
wherein the linking group is an alkylene group, an arylene group, —COO—, an amide linking group, a carbonate linking group, a urethane linking group, a urea linking group, or a group of a combination of these groups.

6. The transfer film according to claim 4,
wherein a content of the repeating unit (a1) is 10% to 70% by mass with respect to all repeating units of the polymer A.

7. The transfer film according to claim 1,
wherein the compound β is a compound B having, as the structure b0, a structure b capable of accepting an electron from the carboxy group in a photoexcited state.

8. The transfer film according to claim 1,
wherein the compound β is a compound B having, as the structure b0, a structure b capable of accepting an electron from the carboxy group in a photoexcited state, and
a total number of the structures b included in the compound B is 5 mol % or more with respect to a total number of the carboxy groups included in the polymer A.

9. The transfer film according to claim 1,
wherein the compound β is a nitrogen-containing aromatic compound.

10. The transfer film according to claim 1,
wherein the compound β is a nitrogen-containing aromatic compound having a substituent.

11. The transfer film according to claim 1,
wherein a molar absorption coefficient ε₃₆₅ of the compound β at a wavelength of 365 nm is 1×10³ (cm·mol/L)⁻¹ or less.

12. The transfer film according to claim 1,
wherein a ratio of a molar absorption coefficient ε₃₆₅ of the compound β at a wavelength of 365 nm to a molar absorption coefficient ε₃₁₃ of the compound β at a wavelength of 313 nm is 3 or less.

13. The transfer film according to claim 1,
wherein a pKa of the compound β in a ground state is 2.0 or more.

14. The transfer film according to claim 1,
wherein a pKa of the compound β in a ground state is 9.0 or less.

15. The transfer film according to claim 1,
wherein the compound β includes one or more selected from the group consisting of isoquinoline and an isoquinoline derivative, quinoline and a quinoline derivative, quinazoline and a quinazoline derivative, quinoxaline and a quinoxaline derivative, and pyridine and a pyridine derivative.

16. The transfer film according to claim 1,
wherein the photosensitive layer further contains a polymerizable compound.

17. The transfer film according to claim 1,
wherein the photosensitive layer further contains a photopolymerization initiator.

18. The transfer film according to claim 17,
wherein the photopolymerization initiator is one or more selected from the group consisting of an oxime ester compound and an aminoacetophenone compound.

19. The transfer film according to claim 1,
wherein the photosensitive layer further contains a polymerizable compound and a photopolymerization initiator, and
a content of the compound β is 1.5% to 7.5% by mass with respect to a total mass of the photosensitive layer.

20. A photosensitive composition comprising:
a polymer A; and
a compound β,
wherein the polymer A includes one or more selected from the group consisting of a repeating unit represented by Formula (a1) and a repeating unit represented by Formula (a2), and
the compound β has a structure b0 which reduces an amount of a carboxy group included in the polymer A by exposure, 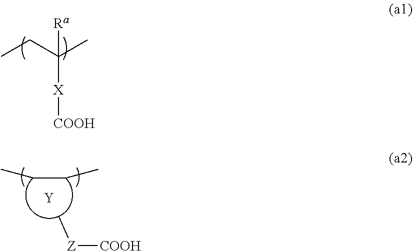
in Formula (a1), R^{a} represents a hydrogen atom or a substituent, and X represents an alkylene group, a cycloalkylene group, an arylene group, —COO—, or a group of a combination of these groups,
in Formula (a2), Y represents a ring group, Z represents a single bond or a linking group, and at least one of Y or Z represents a group having 1 or more carbon atoms.

21. The photosensitive composition according to claim 20,
wherein the repeating unit represented by Formula (a1) has a repeating unit represented by Formula (a1-1), 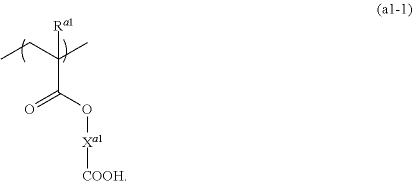
in Formula (a1-1), R^{a1} represents a hydrogen atom or a methyl group, and X^{a1} represents a linking group.

22. The photosensitive composition according to claim 22,
wherein the linking group is an alkylene group, an arylene group, —COO—, an amide linking group, a carbonate linking group, a urethane linking group, a urea linking group, or a group of a combination of these groups.

23. The photosensitive composition according to claim 22,
wherein a content of the repeating unit (a1) is 10% to 70% by mass with respect to all repeating units of the polymer A.

24. The photosensitive composition according to claim 20,
wherein the compound β is a nitrogen-containing aromatic compound.

25. The photosensitive composition according to claim 20,
wherein a molar absorption coefficient ε₃₆₅ of the compound β at a wavelength of 365 nm is 1×10³ (cm·mol/L)⁻¹ or less.

26. The photosensitive composition according to claim 20,
wherein a ratio of a molar absorption coefficient ε₃₆₅ of the compound β at a wavelength of 365 nm to a molar absorption coefficient ε₃₁₃ of the compound β at a wavelength of 313 nm is 3 or less.

27. The photosensitive composition according to claim 20,
wherein the compound β is a compound B having, as the structure b0, a structure b capable of accepting an electron from the carboxy group included in the polymer A in a photoexcited state.

28. The photosensitive composition according to claim 20,
wherein the compound β is a compound B having, as the structure b0, a structure b capable of accepting an electron from the carboxy group included in the polymer A in a photoexcited state, and
a total number of the structures b included in the compound B is 5 mol % or more with respect to a total number of the carboxy groups included in the polymer A.
